(19) United States
(12) Patent Application Publication
(10) Pub. No.: US 2018/0320987 A1
(43) Pub. Date: Nov. 8, 2018

(54) THERMAL STORAGE UNITS, COMPONENTS THEREOF, AND METHODS OF MAKING AND USING THEM

(71) Applicant: BOARD OF REGENTS, THE UNIVERSITY OF TEXAS SYSTEM, Austin, TX (US)

(72) Inventors: Alexandre K. Da Silva, Austin, TX (US); Evan Fleming, Austin, TX (US); Li Shi, Austin, TX (US); Christopher W. Bielawski, Austin, TX (US); Rodney S. Ruoff, Haeundae-gu (KR); Shaoyi Wen, Austin, TX (US); Hengxing Ji, Austin, TX (US); Michael Pettes, Austin, TX (US); Abhijit Paul, Austin, TX (US); Eunsu Paek, Austin, TX (US); Alexander J. Pak, Austin, TX (US); Daniel P. Sellan, Austin, TX (US)

(21) Appl. No.: 16/030,160

(22) Filed: Jul. 9, 2018

Related U.S. Application Data
(63) Continuation of application No. 14/915,403, filed on Feb. 29, 2016, now abandoned.
(60) Provisional application No. 61/871,582, filed on Aug. 29, 2013.
(60) Provisional application No. 61/871,594, filed on Aug. 29, 2013.
(60) Provisional application No. 61/871,714, filed on Aug. 29, 2013.
(60) Provisional application No. 61/871,707, filed on Aug. 29, 2013.

(51) Int. Cl. F28D 20/02; F28F 13/00; B60L 11/18; C09K 5/06; C23C 16/44; F28D 7/08; C01B 32/16; H01M 4/62

(52) U.S. Cl. CPC F28D 20/021; Y02T 10/7005; B60L 11/1829; C09K 5/063; C23C 16/44; F28D 7/082; F28D 20/023; C01B 32/16; Y02E 60/145; H01M 4/625; B60L 2270/44; C01B 2202/36; C01B 2202/34; C01B 2202/24; Y02T 90/14; Y02T 10/7072; Y02T 90/12; Y02T 90/121; Y02T 90/122; Y02T 90/125; F28F 13/003

(57) ABSTRACT

Sugar alcohol blends of galactitol and mannitol and compositions comprising such blends are disclosed as phase change materials (PCMs). A method of forming carbon nanotubes on a carbon substrate is described. Carbon substrates with carbon nanotubes, in particular, conformal layers of carbon nanotubes on carbon substrates, are also disclosed, as are methods of making and using these materials. Thermal storage units are also provided. The thermal storage units can comprise a heat exchange path through which a heat exchange medium flows, and a thermal storage medium in thermal contact with the heat exchange path.

### CROSS-REFERENCE TO RELATED APPLICATIONS

This application claims the benefit of priority to U.S. Provisional Application No. 61/871,582, filed Aug. 29, 2013, U.S. Provisional Application No. 61/871,594, filed Aug. 29, 2013, U.S. Provisional Application No. 61/871,714, filed Aug. 29, 2013, and U.S. Provisional Application No. 61/871,707, filed Aug. 29, 2013, which are all hereby incorporated by this reference herein in their entirities.

### STATEMENT OF GOVERNMENT SUPPORT

This invention was made with government support under Grant No. DE-AR0000178 awarded by the Advanced Research Projects Agency-Energy, a division of the US Department of Energy. The government has certain rights in the invention.

### BACKGROUND

Electric vehicles rely on electrochemical energy storage, typically a Li-ion battery, for propulsion instead of on-board combustion of liquid or gasified fuels. Due primarily to the high cost of Li-ion batteries and limited driving range, electric vehicles (EVs) still represent a small portion of the transportation sector. Significant research efforts are being made to reduce costs and improve energy density of electrochemical storage. Alternatively, if energy demands on the battery were reduced, an extended driving range could be obtained with the same battery.

It has been estimated that as much as 40% of the on-board energy consumed during operation of an EV may be consumed for heating and cooling the cabin of the car in extreme climates. Improved (e.g., lower energy cost) heating and cooling systems for climate conditioning of a vehicle's cabin offer the potential to reduce energy demand on the Li-ion batteries powering the vehicle. In this way, the driving range of the EV can be increased.

Energy related applications such as thermal and electrochemical storage and exchange have great implications on global economy and environment and have been areas of active research and development. In thermal and electrochemical applications, the performance of the thermal and electrochemical apparatus (e.g., an EV) can be greatly improved through incorporation of effective thermal and electronic conductive materials. Graphitic materials in particular have been used in both thermal and electrochemical applications as a viable alternative to the traditional conductive material such as metals. Graphitic materials are generally lightweight, stable, compatible with many different types of thermal and electrochemical active materials, and cost effective. Graphitic materials of continuous and high quality graphite content, however, are difficult to obtain.

Porous metal materials present a broad spectrum of possibilities for advanced applications. In the case of metallic foams, applications include filters, battery and fuel cell electrodes, heat exchangers, catalysts and light-weight structural materials. The advantages of porous metal materials generally relate to high porosity, high surface area and light weight. For many applications, it is desirable that the porosity be as high as possible. Another desirable feature, for many applications, is that the pore volume within the porous metal be highly interconnected, or open. This is particularly true for metallic filters, electrode materials, heat exchangers and catalysts.

Carbon nanotubes have been studied intensively since their discovery in 1991. Nanotubes are found in single sheet wall or multi-wall forms in a wide range of diameters and lengths. These carbon materials have many unusual and valuable properties, such as highly anisotropic (i.e., directional) thermal conductivity. What are needed are new carbon materials and methods of preparing them, as well as methods and devices (e.g., thermal storage units) that utilize them.

Latent heat storage is an important consideration in a wide array of technologies. Latent heat is thermal energy released or absorbed during a change of state of a material without a substantial change in the temperature of the material. The change of state can include a phase change such as a solid-to-liquid, solid-to-gas, liquid-to-gas, or solid-to-solid phase change, such as a crystalline solid to an amorphous solid phase change.

Phase change materials (PCMs) are compositions with high latent heat that undergo such a phase change at a desired temperature. For example, when a PCM freezes, changing from liquid to solid, it releases large amounts of energy in the form of latent heat of fusion. When the material melts, an equal amount of energy is absorbed from the environment as it changes from solid to liquid. Likewise, when a PCM condenses from gas to liquid it releases large amounts of energy in the form of latent heat of vaporization, absorbing an equal amount of energy from the environment as it boils, changing from liquid to gas.

There are many different kinds of PCMs currently available; however, each has its associated advantages and disadvantages that make it suitable for one use but not another. As such, the development of new PCMs is an ongoing aim of research and new PCMs are needed, as are new applications for PCMs.

### SUMMARY

In accordance with the purposes of the disclosed materials, compounds, compositions, articles, devices, and methods, as embodied and broadly described herein, the disclosed subject matter, in one aspect, relates to compositions and methods for preparing and using the disclosed compositions. In particular aspects, the disclosed subject matter, generally relates to compositions that comprise a sugar alcohol blend, which can be used as a PCM. The disclosed sugar alcohol blends contain galactitol and mannitol in certain ratios that provide high heat of fusion and a relatively low melting point. The disclosed compositions can optionally comprise viscosity enhancers, additives, and thermal conductivity modulators. In further aspects, also disclosed are thermal composites that comprise the disclosed compositions and thermal conductivity modulators and devices containing such composites.

Also disclosed herein are methods of forming carbon nanotubes on carbon substrates. Carbon substrates with carbon nanotubes, in particular, conformal layers of carbon nanotubes on carbon substrates, are also disclosed, as are methods of making and using these materials.

Also disclosed herein are three dimensional graphitic matrixes having structures to confer tailored thermal and electric properties. In some embodiments, three dimensional (3D) printing techniques are coupled with chemical vapor deposition or high temperature pyrolysis techniques to produce these 3D graphitic matrixes.

Thermal storage units are also provided herein. The thermal storage units can comprise a heat exchange path through which a heat exchange medium flows, and a thermal storage medium in thermal contact with the heat exchange path. The thermal storage medium can comprise a composite formed from a porous thermally conductive matrix and a phase change material disposed within the porous thermally conductive matrix. The thermally conductive matrix can comprise a metal foam, a carbon- or graphite-containing metal foam, a graphite foam, a carbon foam, a 3D-printed graphite matrix, or combinations thereof. The thermal storage units described herein can be used in any application where the storage of thermal energy is desirable. By way of example, the thermal storage units described herein can be incorporated into HVAC systems in vehicles, such as electric vehicles.

Additional advantages of the disclosed subject matter will be set forth in part in the description that follows, and in part will be obvious from the description, or can be learned by practice of the aspects described below. The advantages described below will be realized and attained by means of the elements and combinations particularly pointed out in the appended claims. It is to be understood that both the foregoing general description and the following detailed description are exemplary and explanatory only and are not restrictive.

### DESCRIPTION OF DRAWINGS

FIG. 1 is a schematic illustration of an exemplary porous graphitic matrix unit.

FIG. 2A is a schematic diagram of an example process to produce a graphitic matrix by stacking two matrix units with offset radius thin walls.

FIG. 2B is a diagram showing the cross sectional view of the graphitic matrix of FIG. 2A.

FIG. 2C is a schematic diagram of an assembled graphitic matrix with a tube inserted in the central opening of the matrix.

FIG. 3 is a diagram showing the graphitic matrixes aligned side by side.

FIGS. 4A and 4B are schematic illustrations of a thermal storage unit.

FIG. 5 is a schematic illustration of a thermal storage unit.

FIG. 6 is a schematic illustration of an HVAC system for use in an EV which includes two thermal storage units.

FIG. 7 is a schematic illustration of an HVAC system for use in an EV which includes two thermal storage units.

### DETAILED DESCRIPTION

The materials, compounds, compositions, articles, and methods described herein may be understood more readily by reference to the following detailed description of specific aspects of the disclosed subject matter and the Examples included therein.

Before the present materials, compounds, compositions, and methods are disclosed and described, it is to be understood that the aspects described below are not limited to specific synthetic methods or specific reagents, as such may, of course, vary. It is also to be understood that the terminology used herein is for the purpose of describing particular aspects only and is not intended to be limiting.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

### General Definitions

In this specification and in the claims that follow, reference will be made to a number of terms, which shall be defined to have the following meanings:

The term “comprising” and variations thereof, such as “comprise” and “comprises,” as used herein is used synonymously with the term “including” and variations thereof and are open, non-limiting terms. Although the terms “comprising” and “including” have been used herein to describe various embodiments, the terms “consisting essentially of” and “consisting of” can be used in place of “comprising” and “including” to provide for more specific embodiments of the invention and are also disclosed.

As used in the description and the appended claims, the singular forms “a,” “an,” and “the” include plural referents unless the context clearly dictates otherwise. Thus, for example, reference to “a composition” includes mixtures of two or more such compositions, reference to “the compound” includes mixtures of two or more such compounds, reference to “an agent” includes mixture of two or more such agents, and the like.

“Optional” or “optionally” means that the subsequently described event or circumstance can or cannot occur, and that the description includes instances where the event or circumstance occurs and instances where it does not.

Ranges can be expressed herein as from “about” one particular value, and/or to “about” another particular value. By “about” is meant within 5% of the value, e.g., within 4, 3, 2, or 1% of the value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

A weight percent (wt. %) of a component, unless specifically stated to the contrary, is based on the total weight of the formulation or composition in which the component is included.

As used herein, the term “graphene” and other forms of the word, such as “graphite” and “graphitic”, is meant to refer to hexagonal carbon. As disclosed herein the graphene layers are said to be substantially pure. By substantially pure is meant that the graphene layer contains about 1% or less (e.g., less that about 0.5%, 0.25%, or 0.1%) of material other than carbon. Further, the graphene layers are said to be substantially free of amorphous carbon, which means that the graphene layer has less than about 10% (e.g., less than about 7%, 5%, 2.5%, or 1%) of the carbon in an amorphous or nonhexagonal configuration. The purity of the graphene can be determined using various techniques, i.e. by phase contrast transmission electron microscopy, X-ray diffraction analysis, Raman spectroscopy, thermal gravimetric analysis, or any combination thereof.

As used herein, the term “conformal layer” is meant to refer to a substantially uniform thickness deposited on substantially all surfaces of a substrate. By “substantially uniform thickness” is meant that the variation in thickness is less than 10%. By “substantially all surfaces of a substrate” is meant more than 90% of the surface area of the substrate.

Reference will now be made in detail to specific aspects of the disclosed materials, compounds, compositions, articles, and methods, examples of which are illustrated in the accompanying Examples and Figures.

Sugar Alcohol Blends with High Latent Heat

A high latent heat of fusion is desirable for thermal storage applications, as it determines the effective thermal energy density. However, heat of fusion is generally proportional to melting temperature, and from an application standpoint, higher melting temperatures can have undesired drawbacks, depending on the application, e.g., need for better insulation. The disclosed PCM compositions retain a high latent heat through blending two high latent heat materials (galactitol and mannitol), but the resulting material has a lower melting temperature than either pure material. The disclosed PCM compositions also have high thermal stability and are noncorrosive, which is a common disadvantage of PCMs based on fatty acids.

Disclosed herein are blends of two sugar alcohols: galactitol and mannitol, and PCM compositions comprising such blends.

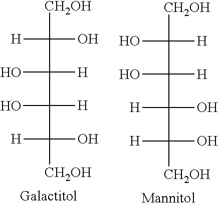 [SMILES: OCC(O)C(O)C(O)C(O)CO ; OCC(O)C(O)C(O)C(O)CO]

Galactitol has a latent heat of fusion of 357 J/g and a melting point of 187° C. Mannitol has a latent heat of fusion of 308 J/g and a melting point of 162° C. It has been found that certain blends of these two sugar alcohols maintain a high latent heat of fusion with a low melting point, lower than either pure component, making the blend a suitable component for PCMs and medium temperature thermal storage applications.

Galactitol and mannitol can be present in the disclosed blends in a weight ratio of from about 9:1 to about 1:9. For example, the weight ratio of galactitol to mannitol can be about 9:1, about 8.5:1, about 8:1, about 7.5:1, about 7:1, about 6.5:1, about 6:1, about 5.5:1, about 5:1, about 4.5:1, about 4:1, about 3.5:1, about 3:1, about 2.5:1, about 2:1, about 1.5:1, about 1:1, about 1:1.5, about 1:2, about 1:2.5, about 1:3, about 1:3.5, about 1:4, about 1:4.5, about 1:5, about 1:5.5, about 1:6, about 1:6.5, about 1:7, about 1:7.5, about 1:8, about 1:8.5, or about 1:9, where any of the stated ratios can form the upper or lower end point of a range of ratios. In other examples, the weight ratio of galactitol to mannitol is from about 2.5:1 to about 1:1.5. For example, the weight ratio of galactitol to mannitol can be about 2.5:1, about 2:1, about 1.5:1, about 1:1, and about 1:1.5, where any of the stated ratios can form the upper or lower end point of a range of ratios. In a further preferred example, the weight ratio of galactitol to mannitol can be from about 2:1 to about 1:1. In a most preferred example, the weight ratio of galactitol to mannitol is about 1:1.

The galactitol and mannitol blend is the major component of the disclosed PCM compositions. For example, the amount of the galactitol and mannitol blend can be at least about 75 wt. % of the total composition. In other examples, the amount of galactitol and mannitol blend can be at least about 75, about 80, about 85, about 90, about 95, about 98, or about 99 wt. % of the total composition, where any of the stated values can form an upper or lower endpoint of a range.

The disclosed blends and compositions comprising them can have a melting point from about 150 to about 160° C., for example, about 150, about 151, about 152, about 153, about 154, about 155, about 156, about 157, about 158, about 159, or about 160° C., where any of the stated values can form an upper or lower endpoint of a range. In a preferred example, the disclosed blends and compositions containing them can have a melting point of from about 151 to about 153° C.

The disclosed blends and compositions comprising them can have a latent heat of fusion of from about 280 to about 315 J/g, for example, about 280, about 285, about 290, about 295, about 300, about 305, about 310, and about 315 J/g, where any of the stated values can form an upper or lower endpoint of a range. In a preferred example, the disclosed blends and compositions containing them can have a latent heat of fusion of from about 300 to about 310 J/g.

The melting enthalpy of the blends and compositions comprising them can be from about 100 to about 700 MJ/m³. For example, the melting enthalpy can be about 100 MJ/m³, about 150 MJ/m³, about 200 MJ/m³, about 250 MJ/m³, about 300 MJ/m³, about 350 MJ/m³, about 400 MJ/m³, about 450 MJ/m³, about 500 MJ/m³, about 550 MJ/m³, about 600 MJ/m³, about 650 MJ/m³, or about 700 MJ/m³, where any of the stated values can form an upper or lower endpoint of a range.

The disclosed blends and compositions comprising them can, in a preferred example, comprise galactitol and mannitol in a weight ratio of about 1:1, has a melting point of about 151 to about 153° C., and a latent heat of fusion of from about 300 J/g to about 310 J/g.

It is also contemplated herein that either one or both of the sugar alcohols can be chemically modified to adjust their latent heat of fusion and melting point and thus the latent heat of fusion and melting point of the blend. For example, the galactitol and/or mannitol can be oxidized or reduced at one or more positions. Alternatively or additionally, the galactitol and/or mannitol can be functionalized with an alkyl, amino, amido, cyano, thio, or ester group at one or more positions. The galactitol and/or mannitol can also be converted into their pyranose or furanose forms.

By modifying the galactitol and/or mannitol the melting point of the blend can be lowered. Thus, in this case the blends can have a melting point from about 120 to about 160° C., for example, about 120, about 121, about 122, about 123, about 124, about 125, about 126, about 127, about 128, about 129, about 130, about 131, about 132, about 133, about 134, about 135, about 136, about 137, about 138, about 139, about 140, about 141, about 142, about 143, about 144, about 145, about 146, about 147, about 148, about 149, about 150, about 151, about 152, about 153, about 154, about 155, about 156, about 157, about 158, about 159, or about 160° C., where any of the stated values can form an upper or lower endpoint of a range. In a preferred example, the disclosed compositions can have a melting point of from about 120 to about 150° C., from about 130 to about 150° C., or from about 140 to about 150° C.

The disclosed compositions can optionally comprise one or more viscosity modifiers. For example, the viscosity modifier in the disclosed composition can be glycerol, erythritol, threitol, arabitol, xylitol, ribitol, sorbitol, dulcitol, iditol, isomalt, maltitol, or lactitol. In other examples, a suitable viscosity modifier in the disclosed compositions can be a diisocyanate, such as methylene diphenyl diisocyanate (MDI), toluene diisocyanate (TDI), naphthalene diisocyanate (NDI), isophorone diisocyanate (IPDI), and/or hexamethylene diisocyanate (HDI).

The disclosed compositions can optionally comprise one or more additives. One type of additive that can be included in the disclosed compositions is an antimicrobial. Because the disclosed compositions contain sugar alcohols, microbial growth can be a concern in certain situations. Thus, any antimicrobial material that can prevent or reduce microbial growth in the disclosed compositions can be used. Examples of suitable antimicrobial materials include metals such as copper, zinc, or silver and/or salts thereof. Further examples of suitable antimicrobial materials include natural and synthetic organic compositions such as β-lactam antibiotics like penicillin or cephalosporin, and protein synthesis inhibitors like neomycin. Antimicrobial materials such as lactic acid, acetic acid, or citric acid can also be used. In some other examples, an antimicrobial material can comprise a quarternary ammonium compound such as benzalkonium chloride, benzethonium chloride, methylbenzethonium chloride, cetylalkonium chloride, cetylpyridinium chloride, cetrimonium, cetrimide, dofanium chloride, tetraethylammonium bromide, didecyldimethylammonium chloride, and domiphen bromide. The antimicrobials can be used in effective amounts, e.g., an amount that will prevent or reduce microbial growth while not substantially affecting the latent heat and melting point of the blend.

Another suitable additive that can be included in the disclosed compositions is a fire retardant. Suitable fire retardants can comprise an organic composition or an inorganic composition. In some examples, a suitable fire retardant such as tris(2-chloro-1-(chloromethyl)ethyl)phosphate, aluminum hydroxide, magnesium hydroxide. In some embodiments, a fire retardant can comprise a zeolite. The fire retardants can be used in effective amounts, e.g., an amount that will prevent or reduce combustion while not substantially affecting the latent heat and melting point of the blend.

Still further, the disclosed compositions can optionally comprise agents to prevent supercooling. Suitable examples of such agents include sparingly soluble inorganic salts such as calcium sulfate, calcium pyrophosphate silver iodide.

The disclosed compositions can optionally comprise a thickener such as water insoluble super adsorbent polymer (acrylic acid copolymer) carboxymethyl cellulose, cationic guar gum, or fumed silica.

The disclosed compositions can optionally comprise an antioxidant such as amine or hydroxyamines, or phenols.

The disclosed compositions can optionally comprise a corrosion inhibitor such as sodium sulfite, chromates, and polyphosphates.

The disclosed blends or compositions containing them can be combined with one or more thermal storage materials. For example, fatty acid, paraffin, polyethylene glycol, polyvinyl alcohol, glycerin, polyethylene, and crosslinked polyethylene can be combined with the blends or compositions comprising them.

Other additional thermal storage materials that can be combined herein are urea; ureidopyrimidone; N,N-dialkylpiperidinum; N,N-dialkylpyrrolidinium; LiF and BeF₂; NaF and BeF₂; LiF and NaF and KF; NaF and ZrF₄; KNO₃ and KCl; KNO₃ and K₂CO₃; LiBr and KBr; KNO₃ and KBr; KNO₃ and LiOH; FeCl₂ and KCl; KCl and LiCl; K₂CO₃ and KOH; K₂SO₄ and KOH; FeCl₂ and NaCl; KCl and MnCl₂; LiBr and LiI; KCl—MgCl₂; MnCl₂ and NaCl; LiCO₃ and LiOH; LiBr and LiF; NaCl and MgCl₂; K₂CO₃ and MgCO₃; KF and KBF₄; Na₂SO₄ and ZnSO₄; CaCl₂ and LiCl; LiCl and Li₂SO₄; KF and LiF; K₂CO₃ and Li₂CO₃; Li₂CO₃ and Na₂CO₃; LiCl and LiF; CaCl₂ and NaCl; KVO₃ and BaTiO₃; KCl and LiBr and NaBr; KBr and LiCl and NaCl; LiBr and NaBr and KBr; NaOH and NaCl and Na₂CO₃; KCl and LiCl and Li₂SO₄; MgCl₂ and KCl and NaCl; NaCl and KCl and FeCl₂; KCl and LiCl and CaF₂; CaCl₂ and KCl and LiCl; NaCl and KCl and LiCl; KF and AlF₃ and ZrF₄; MnCl₂ and KCl and NaCl; Na₂SO₄ and K₂SO₄ and ZnSO₄; Na₂CO₃ and K₂CO₃ and ZnSO₄; Na₂CO₃ and K₂CO₃ and LiCO₃; KCl and NaCl and LiF; LiCl and NaCl and Li₂SO₄; LiCl and KCl and CaCl₂ and CaF₂; KCl and NaCl and LiCl and Li₂SO₄; NaNO₃; KNO₃; KNO₃ and KCl; KNO₃ and K₂CO₃; KNO₃ and KBr; FeCl₂ and KCl; KCl and LiCl; K₂CO₃ and KOH; K₂SO₄ and KOH; FeCl₂ and NaCl; LiBr and KBr; NaOH and NaCl and Na₂CO₃; MgCl₂ and KCl and NaCl; NaCl and KCl and FeCl₂; CaCl₂ and KCl and LiCl; MgCl₂ and KCl and NaCl; MgCl₂ and KCl and NaCl; NaOH and NaCl and Na₂CO₃; MnCl₂ and KCl and NaCl; Na₂CO₂ and K₂CO₃ and Li₂CO₃; LiF and LiCl and LiVO₃ and Li₂SO₄ and Li₂MoO₄; LiF and LiCl and Li₂SO₄ and Li₂MoO₄; LiF and KF and KCO₄ and KCl; LiF and LiOH; LiF and BaF₂ and KF and NaF; LiF and KF and NaF and KCl; LiF and NaF and KF and MgF₂; LiF and NaF and KF; LiF and KF and NaF; LiF and NaF and KF; LiF and LiCl; KF and LiCl; KF and LiCl; LiF and KF; LiF and LiVO₃ and Li₂MoO₄; LiCl and KCl and LiCO₃ and LiF; LiCl and KCl; KCl and MnCl₂ and NaCl; LiClLiVO₃ and Li₂MoO₄ and Li₂SO₄ and LiF; NaCl and KCl and MgCl₂; KCl and MgCl₂ and NaCl; NaCl and MgCl₂; KCl and ZnCl₂; KCl and MgCl₂; NaCl═MgCl₂; LiCl and Li₂SO₄ and Li₂MoO₄; KCl and MnCl₂; LiCl and Li₂SO₄ and LiVO₃; KCl and MnCl₂; NaCl and MgCl₂; CaCl₂ and KCl and NaCl and NaF; CaCl₂ and KCl and MgCl₂ and NaCl; CaCl₂ and KCl and NaCl; KCl and MgCl₂; LiCl and LiF and MgF₂; CaCl₂ and CaF₂ and NaF; CaCl₂ and NaCl; NaOH and NaCl and Na₂CO₃; LiOH and LiF; Li₂CO₃ and K₂CO₃ and Na₂CO₃; Li₂CO₃ and K₂CO₃; Li₂CO₃ and K₂CO₃; Zn and Mg; Al and Mg and Zn; Mg and Cu and Zn; Mg and Cu and Ca; Mg and Al; formic acid; caprilic acid; glycerin; D-Lactic acid; methyl palmitate; camphenilone; docasyl bromide; caprylone; phenol; heptadecanone; 1-cyclohexylooctadecane; 4-heptadacanone; p-joluidine; cyanamide; methyl eicosanate; 3-heptadecanone; 2-heptadecanone; hydrocinnamic acid; cetyl alcohol; α-nepthylamine; camphene; O-nitroaniline; 9-heptadecanone; thymol; sodium acetate; trimethylolethane; methylbehenate; diphenyl amine; p-dichlorobenzene; oxalate; hypophosphoric acid; O-xylene dichloride; β-chloroacetic acid; nitro naphthalene; trimyristin; heptaudecanoic acid; α-chloroacetic acid; bees wax; glycolic acid; glyolic acid; p-bromophenol; azobenzene; acrylic acid; dinto toluent; phenylacetic acid; thiosinamine; bromcamphor; durene; benzylamine; methyl bromobenzoate; alpha napthol; glautaric acid; p-xylene dichloride; catechol; quinine; acetanilide; succinic anhydride; benzoic acid; stibene; benzamide; acetic acid; polyethylene glycol; capric acid; eladic acid; lauric acid; pentadecanoic acid; trustearin; myristic acid; palmatic acid; stearic acid; acetamide; methyl fumarate; K₂HPO₄.6H₂O; FeBr₃.6H₂O; Mn(NO₃)₂.6H₂O; FeBr₃.6H₂O; CaCl₂.12H₂O; LiNO₃.2H₂O; LiNO₃.3H₂O; Na₂CO₃.10H₂O; Na₂SO₄.10H₂O; KFe(SO₄)₂.12H₂O; CaBr₂.6H₂O; LiBr₂.2H₂O; Zn(NO₃)₂.6H₂O; FeCl₃.6H₂O; Mn(NO₃)₂.4H₂O; Na₂HPO₄.12H₂O; CoSO₄.7H₂O; KF.2H₂O; MgI₂.8H₂O; CaI₂.6H₂O; K₂HPO₄.7H₂O; Zn(NO₃)₂.4H₂O; Mg(NO₃).4H₂O; Ca(NO₃).4H₂O; Fe(NO₃)₃.9H₂O; Na₂SiO₃.4H₂O; K₂HPO₄.3H₂O; Na₂S₂O₃.5H₂O; MgSO₄.7H₂O; Ca(NO₃)₂.3H₂O; Zn(NO₃)₂.2H₂O; FeCl₃.2H₂O; Ni(NO₃)₂.6H₂O; MnCl₂.4H₂O; MgCl₂.4H₂O; CH₃COONa.3H₂O; Fe(NO₃)₂.6H₂O; NaAl(SO₄)₂.10H₂O; NaOH.H₂O; Na₃PO₄.12H₂O; LiCH₃COO.2H₂O; Al(NO₃)₂.9H₂O; Ba(OH)₂.8H₂O; Mg(NO₃)₂.6H₂O; KAl(SO₄)₂.12H₂O; MgCl₂.6H₂O; gallium-gallium antimony eutectic; gallium; cerrolow eutectic; Bi—Cd—In eutectic; cerrobend eutectic; Bi—Pb—In eutectic; Bi—In eutectic; Bi—Pb-tin eutectic; Bi—Pb eutectic; CaCl₂.6H₂O and CaBr₂.6H₂O; Triethylolethane and water and urea; C₁₄H₂₈O₂ and C₁₀H₂₀O₂; CaCl₂ and MgCl₂.6H₂O; CH₃CONH₂ and NH₂CONH₂; Triethylolethane and urea; Ca(NO₃).4H₂O and Mg(NO₃)₃.6H₂O; CH₃COONa.3H₂O and NH₂CONH₂; NH₂CONH₂ and NH₄NO₃; Mg(NO₃)3.6H₂O and NH₄NO₃; Mg(NO₃)₃.6H₂O and MgCl₂.6H₂O; Mg(NO3)3.6H₂O and MgCl₂.6H₂O; Mg(NO3)3.6H₂O and Al(NO₃)₂.9H₂O; CH₃CONH₂ and C₁₇H₃₅COOH; Mg(NO₃)₂.6H₂O and MgBr₂.6H₂O; Napthalene and benzoic acid; NH₂CONH₂ and NH₄Br; LiNO₃ and NH₄NO₃ and NaNO₃; LiNO₃ and NH₄NO₃ and KNO₃; LiNO₃ and NH₄NO₃ and NH₄Cl; or combinations thereof

The combination of the thermal storage materials and the disclosed compositions with galactitol and mannitol blends can reduce the melting point to, e.g., from about 160° C. to about 120° C., from about 150° C. to about 130° C., from about 140° C. to about 130° C., or from about 240° C. to about 150° C.

The disclosed blends or compositions containing them can also be microencapsulated. There are a variety of suitable ways to microencapsulate these compositions, e.g., vapor phase deposition, fluid bed coating, entrapment/matrix encapsulations, spray-dried emulsions, dispersion polymerization, in situ polymerization, interfacial polymerization, simple coacervation, complex coacervation, solvent phase separation, liposomal encapsulations, pan coating, etc.

Also disclosed herein are thermal composites that comprise the disclosed blends or compositions containing them. For example, a thermal composite can contains a galactitol and mannitol blend, as disclosed herein, and a thermal conductivity modulator. The thermal conductivity modulator can be a highly porous isotropic or anisotropic matrix. For example, the porous matrix can comprise a volume porosity of at least about 75% (e.g., at least about 80%, at least about 85%, at least about 90%, at least about 91%, at least about 92%, at least about 93%, at least about 94%, at least about 95%, at least about 96%, at least about 97%, at least about 98%, or at least about 99%). In certain examples, the matrix can comprise a thermally conductive foam. The foam can comprise closed cells, open cells, a coarse porous reticulated structure, and/or combinations thereof. In certain examples, the foam can comprise an open-cell foam or a reticulated foam, so as to allow the PCM to be dispersed throughout the foam.

In certain examples, the thermally conductive modulator can comprise a metal foam. Metallic foams, including open-celled metal foams and reticulated metal foams, are known in the art, and can be produced using a variety of liquid and solid state processing methods. Suitable methods for forming metal foams can be selected in view of a number of factors, including the composition of the metal foam and the desired foam morphology (e.g., the desired volume porosity). Non-limiting examples of metals can may be included in metal foams include aluminum (Al), titanium (Ti), iron (Fe), nickel (Ni), copper (Cu), vanadium (V), cobalt (Co), zinc (Zn), cadmium (Cd), tin (Sn), tungsten (W), chromium (Cr), niobium (Nb), and molybdenum (Mo). The metal foam can comprise substantially only a single metal. Alternatively, the metal foam can comprise a combination of two or more metals. Examples of suitable metal foams include, but are not limited to, nickel foams, aluminum foams, titanium foams, bronze foams, and copper foams. In certain cases, the metal foam comprises a reticulated metal foam. Methods of making reticulated metal foams are known in the art. See, for example, U.S. Pat. No. 6,857,461 to Girlich which is incorporated herein by reference. The thermally conductive matrix can also comprise a carbon- or graphite-containing metal foam, such as a carbon- or graphite-containing nickel foam, aluminum foam, titanium foam, bronze foam, or copper foam.

Further examples of suitable thermal conductivity modulators include carbon substrates like graphitic carbon, carbon black, and carbon nanoparticles. A carbon nanoparticle can comprise a carbon nanotube, fullerene, or graphene. In preferred examples, the thermal conductivity modulator comprises a carbon foam. Carbon and graphite foams can comprise three dimensional interconnected carbonaceous structures that exhibit high thermal conductivity. Carbon and graphite foams can be configured in a wide range of geometries based on application needs and/or heat transfer requirements. In particular, carbon and graphite foams can be configured to exhibit a high thermal conductivity, a low density, or combinations thereof. In certain embodiments, the carbon and graphite foam can be an open cell or reticulated carbon and graphite foam having a small cell or pore size. Three dimensional carbon foams, including ultrathin graphite foams, suitable for use herein are disclosed in Pettes et al., Nano Lett, 12:2959-2964, 2012, and Ji et al., Nano Lett, 12:2446-2451, 2012, which are each incorporated by reference herein in their entireties for their teachings of graphite foams and methods of making and using them. The graphite foam comprises three dimensional interconnected graphite structures that are highly conductive. When the pores of the foam are filled with active material such as PCM disclosed herein for thermal exchange or storage applications, the three dimensional interconnected graphite structures can efficiently transport heat from the active materials embedded in the pores of the graphite foam. The three dimensional interconnected graphite structures of the graphite foam can provide a three dimensional matrix that features torturous pores surrounded by correspondingly torturous interconnected walls. These torturous interconnected walls of the graphite foam have been further modified by introducing carbon nanomaterials into the pores of the matrix. In a particular example, the thermal conductivity modulator is a 3D printed graphite foam.

For example, graphite foams can be synthesized by chemical vapor deposition (CVD) of a suitable carbon precursor on an open-celled reticulated nickel foam. After the graphite has been formed on the nickel foam, the nickel can be removed, for example using a wet etchant, to afford a graphite foam. Other suitable carbon and graphite foams include pitch-based carbon and graphite foams. See, for example, U.S. Pat. Nos. 6,033,506, 6,037,032, 6,399,149, 6,780,505, 7,014,151, 7,157,019, 7,166,237, 6,261,485, 6,387,343, 6,656,443, and 6,663,842 to Klett, all of which are incorporated herein by reference in their entirety. Suitable carbon and graphite foams, such as reticulated vitreous carbon (RVC) foams, can also be obtained from commercial sources. For example, suitable foams are commercially available under the trade name POCOFOAM® (by Poco Graphite, Inc., Decatur, Tex.).

In certain embodiments, the thermally conductive matrix can comprise a 3D-printed graphite matrix. 3D-printed graphitic matrixes are graphitic materials formed using a 3-D printed template. 3D-printing can provide precise control over the morphology of the graphitic material. Accordingly, 3D-printed graphitic matrixes can possess a structure comprising a microporous network formed of continuous graphitic material.

The 3D-printed graphitic matrix can be formed so as to possess any suitable morphology. Methods for preparing 3D-printed graphite matrixes can comprise forming a microporous template using a 3D-printing processes, and graphitizing the microporous template to yield a 3D-printed graphitic matrix. The microporous template can be formed from any suitable graphitizable material which can be printed using standard 3-D printing methods. For example, the microporous template can be a metal template (e.g., a nickel template) or a graphitizable polymer template. Metal (e.g., Ni) templates can be formed via Direct Metal Laser Sintering (DMLS) of metal (e.g., Ni) powders. DMLS uses a small diameter laser to sinter metal powders to form a metallurgic bond. The laser path is controllable and by continually adding more layers of metal powder, a microporous metal template can be printed based on a digital model. A variety of 3D-printing processes, including stereolithography and selective laser sintering, can be used to form microporous polymer templates. The structure of the template can be individually designed for a specific application, i.e., rationally designed. For example, the 3D graphitic matrix can be designed to have a structure that corresponds to a desired path for thermal transmission.

Once formed using 3-D printing methods, the microporous template can be graphitized. Methods for graphitizing the matrix can vary depending upon a number of factors, including the composition of the microporous template. Metal templates (e.g., Ni templates) can be graphitized using high temperature chemical vapor deposition (CVD) to form a graphite matrix on the surface of the metal template. Once the graphite matrix has been formed, the metal template can be etched away, as described above. Templates formed from a graphitizable polymer can graphitized through pyrolysis of the graphitizable polymer. This process can form a 3D-graphitic matrix directly from the microporous template. Polymer templates can also be graphitized by metalizing the polymer template, and then graphitizing the metalized polymer template using the methods described above for graphitizing metal templates.

In a preferred aspect, the thermal conductivity modulation is a hybrid material comprising a conformal layer of carbon nanotubes on a porous carbon substrate, as described herein more fully below.

The carbon substrate can be selected from the group consisting of a carbon foam, a graphite foam, and a 3D printed graphite foam. The thickness of the graphene walls in the carbon substrate can be varied, depending on how certain parameters are adjusted in the synthesis. For example, by using a nickel foam with thicker strut walls, increasing vapor deposition times, and increasing the concentration of carbon precursor can thicken the graphene walls of the carbon substrate. In general, the thickness of the walls of the carbon substrate can be from about 2 nm to about 500 nm in thickness, e.g., about 2, about 50 nm, about 100 nm, about 150 nm, about 200 nm, about 250 nm, about 300 nm, about 350 nm, about 400 nm, about 450 nm, or about 500 nm, wherein any of the stated values can form an upper or lower endpoint of a range.

The carbon nanotubes form a “forest” on the carbon substrate and can be from about 1 to about 500 μm in length. The carbon nanotubes on the carbon substrate can be from about 1 to about 50 nm in diameter. In some examples, the carbon nanotubes can comprise single walled nanotubes, double walled nanotubes, multi-walled nanotubes, or a combination thereof.

The carbon nanotubes can be formed the carbon substrate by any of the processes described herein more fully below.

The disclosed PCMs, and thermal composites including them, are suitable for medium temperature range applications. For example, the disclosed compositions and composites can be used in thermal controllers for reactors or thermal energy storage devices.

One particular device contemplated herein is a thermal battery. Electric vehicles (EVs) often suffer from inefficient heating and cooling systems that can limit their driving range by acting as a drain on their batteries. Rechargeable thermal energy storage-based hot-and-cold batteries can provide efficient heating and cooling to EVs without draining the on-board battery packs, in effect extending the driving range of EVs. The disclosed PCM composition can be used in a high-energy density and low-cost thermal storage system that can provide efficient cabin heating and cooling for EVs. Such thermal batteries can also be incorporated into the heating and cooling systems in buildings, enhancing the energy efficiency and reducing emissions.

In some examples, the thermal storage units can include a shell and tube-type heat exchanger, as described herein more fully below.

### Carbon Foam/Carbon Nanotube Hybrid Materials

Also disclosed herein are methods of forming carbon nanotubes on a carbon substrate. The method comprises the steps of depositing a buffer layer on the carbon substrate by atomic layer deposition, depositing a catalyst on the carbon substrate and/or buffer layer, and contacting the substrate with a working gas at an elevated temperature, i.e., a temperature sufficient to cause decomposition of the working gas, thereby forming carbon nanotubes on the carbon substrate.

The carbon substrate can be selected from the group consisting of a carbon foam, a graphite foam, and a 3D printed graphite foam. Preferably the carbon substrates are highly porous, as are carbon and graphite foams. Carbon and graphite foams can be synthesized through the use of methane chemical vapor deposition (CVD) on an open-celled reticulated nickel foam. A variety of chemical vapor apparatus can be used. A chemical vapor deposition apparatus typically comprises a horizontal tubular reactor equipped with a susceptor for mounting a substrate thereon, a heater for heating the substrate, a feed gas introduction portion arranged such that the direction of the feed gas fed in a tubular reactor is made parallel to the substrate, and a reaction gas exhaust portion. Thus the substrate is placed on the susceptor in the tubular reactor, the substrate is heated, and a gas containing a feed gas is supplied in the reactor in the direction parallel to the substrate so that a chemical vapor deposition forms a film on the substrate. See U.S. Pat. 6,926,920, U.S. Publication No. 2002-0160112, which are incorporated by reference herein for their teachings of CVD techniques.

The feed gas is a carbon precursor, for example, xylene, toluene, benzene, methane, ethane, and the like. A carrier gas, such as a mixture of hydrogen and argon, can also be used.

After the graphite has been formed on the nickel foam, the Ni is removed. In some examples, the Ni can be removed using a wet etchant. Examples of suitable wet etchants include dilute hydrochloric acid, iron(III) chloride, iron(III) nitrate, ammonium persulfate, and boric acid. In some examples, the Ni can be removed using electrolytic etching. For example, the nickel/graphite foam is attached to an anode and a nickel foil is attached to a cathode of a DC power source, both are immersed in an electrolyte and DC voltage is applied to remove the nickel from the foam. Examples of suitable electrolyte solutions include a mixture of an acid, a nickel salt, and a surfactant. Examples of suitable acids include boric acid, hydrochloric acid, nitric acid, and sulfuric acid. Examples of suitable nickel salts include nickel sulfate, nickel nitrate, nickel chloride, and combinations thereof. Examples of suitable surfactants include sodium dodecyl, cetylpyridium chloride, octaethylene glycol, and combinations thereof. The DC voltage can be in the range of from about 1 to about 8 V, e.g., about 1 V, about 2 V, about 3 V, about 4 V, about 5 V, about 6 V, about 7 V, or about 8 V, where any of the stated values can form an upper or lower endpoint of a range. The DC voltage can be applied for from about 1 to about 60 minutes, e.g., for at least about 1 minute, about 5 minutes, about 10 minutes, about 15 minutes, about 20 minutes, about 25 minutes, about 30 minutes, about 35 minutes, about 40 minutes, about 45 minutes, about 50 minutes, about 55 minutes, or about 60 minutes, where any of the stated values can form an upper or lower endpoint of a range.

A carbon nanotube “forest” is grown on the carbon substrate with the use of a uniform buffer and/or catalyst layer(s). To achieve such a layer(s) with uniform coverage on the surface of carbon substrate, the effects due to shadowing are mitigated. Catalyst and buffer layers have been prepared on flat substrates by using physical vapor deposition, e.g., e-beam evaporation, thermal evaporation and sputtering deposition. Such methods fail for carbon and graphite foams due to the strong shadowing effect of the three-dimensional porous structure. Solution based processes avoid the shadowing effect; however, the uniformity in both coverage and thickness of the layers is poor.

Disclosed herein is the use of atomic layer deposition (ALD) to deposit conformal thin-films of varying compositions. A uniform coating on the carbon substrate comprising catalyst and/or buffer layers is achieved with ALD, and a carbon nanotube “forest” on the whole carbon substrate can be obtained.

Atomic layer deposition is a thin film deposition technique that is based on the sequential use of a gas phase chemical process. The majority of ALD reactions use two chemicals, typically called precursors. These precursors react with a surface one at a time in a sequential, self-limiting, manner. By exposing the precursors to the growth surface repeatedly, a thin film is deposited.

ALD is a self-limiting (the amount of film material deposited in each reaction cycle is constant), sequential surface chemistry that deposits conformal thin-films of materials onto substrates of varying compositions. Due to the characteristics of self-limiting and surface reactions, ALD film growth makes atomic scale depositions control possible. ALD is similar in chemistry to chemical vapor deposition, except the ALD reaction breaks the CVD reaction into two half-reactions, keeping the precursor materials separate during the reaction. By keeping the precursors separate throughout the coating process, atomic layer control of film growth can be obtained as fine as ˜0.1 Å per cycle. Separation of the precursors is accomplished by pulling a purge gas (such as nitrogen or argon) after each precursor pulse to remove excess precursor from the process chamber and prevent ‘parasitic’ CVD deposition on the substrate.

The growth of material layers by ALD involves repeating the following characteristic four steps: (1) contacting the substrate with the first precursor; (2) purge or evacuation of the reaction chamber to remove the non-reacted precursors and the gaseous reaction by-products; (3) contacting the substrate with the second precursor—or another treatment to activate the surface again for the reaction of the first precursor, such as a plasma; (4) purge or evacuation of the reaction chamber. Each reaction cycle adds a given amount of material to the surface of the substrate, referred to as the growth per cycle. To grow a material layer, reaction cycles are repeated as many times as required for the desired film thickness. One cycle may take from about 0.5 seconds to a few seconds and deposit from about 0.1 to about 3 Å of film thickness. Due to the self-terminating reactions, ALD is a surface-controlled process, where process parameters other than the precursors, substrate, and temperature have little or no influence. And, because of the surface control, ALD-grown films are extremely conformal and uniform in thickness. These thin films can also be used in correlation with other common fabrication methods.

Using ALD, film thickness depends only on the number of reaction cycles, which makes the thickness control accurate and simple. There is less need of reactant flux homogeneity, which gives large area (large batch and easy scale-up) capability, excellent conformality and reproducibility, and simplifies the use of solid precursors. Also, the growth of different multilayer structures is straight forward. Other advantages of ALD are the wide range of film materials available, high density and low impurity level. Also, lower deposition temperature can be used in order not to affect sensitive substrates.

In the disclosed methods, a buffer layer is deposited on the carbon substrate by atomic layer deposition. A catalyst is deposited on the carbon substrate and/or buffer layer, depending on whether the catalyst is deposited before or after the buffer layer. The catalyst layer can be deposited by ALD or by other depositing methods disclosed herein. Then the substrate, with the buffer and catalyst layers, is contacted with a working gas at a temperature sufficient to cause decomposition of said gas, thereby forming carbon nanotubes on the carbon substrate. In some examples, the deposition of the buffer layer can be performed before the catalyst is deposited. In other examples, the catalyst can be deposited before the buffer layer is deposited.

It can be desired to plasma treat the carbon substrate prior to ALD deposition of the buffer layer. In a plasma, gas atoms are excited to higher energy states and also ionized. Gases such as argon and oxygen, as well as mixtures such as air and hydrogen/nitrogen are used. Plasma treatment can be used to remove impurities and contaminants from surfaces and/or modify the hydrophobicity of a surface, i.e., turn a surface from hydrophobic to hydrophilic. In some examples, the carbon substrate is oxygen plasma treated for from about 1 to about 5 minutes prior to atomic layer deposition. For example, the carbon substrate is oxygen plasma treated for at least about 1 minute, about 1.5 minutes, about 2 minutes, about 2.5 minutes, about 3 minutes, about 3.5 minutes, about 4 minutes, about 4.5 minutes, or about 5 minutes.

When applying the buffer layer by ALD, the buffer layer can be applied from about 1 to about 10 nm thick, e.g., about 1 nm, about 2 nm, about 3 nm, about 4 nm, about 5 nm, about 6 nm, about 7 nm, about 8 nm, about 9 nm, or about 10 nm thick, where any of the stated values can form an upper or lower endpoint of a range. Examples of materials that can be used as the buffer layer are aluminum, iridium, a metal nitride or a metal oxide. Examples of metal nitrides are titanium nitride, tantalum nitride and silicon nitride. Examples of metal oxides are aluminum oxide, zinc oxide, silicon oxide, and titanium oxide. In a specific example, the buffer layer can be an aluminum oxide layer from about 2 to about 10 nm thick, e.g., about 1 nm, about 2 nm, about 3 nm, about 4 nm, about 5 nm, about 6 nm, about 7 nm, about 8 nm, about 9 nm, or about 10 nm thick, where any of the stated values can form an upper or lower endpoint of a range. In a preferred example, the buffer layer can be an about 5 nm thick layer of aluminum oxide.

As noted, the catalyst can be deposited by atomic layer deposition. In other examples, the catalyst can be deposited using chemical vapor deposition. In still other examples, the catalyst can be deposited from a vapor phase metal source.

Examples of suitable catalysts that can be deposited are iron, nickel, cobalt, molybdenum, or combinations thereof; a nickel/chromium/iron alloy; and an iron/copper/magnesium oxide combination. In a preferred example, the catalyst is an iron catalyst. In preferred example, the iron catalyst is derived from ferrocene.

The catalyst can be deposited as a layer on the carbon substrate or buffer. For example, the catalyst can be deposited as a layer that is from about 2 to about 20 nm thick, e.g., about 2 nm, about 3 nm, about 4 nm, about 5 nm, about 6 nm, about 7 nm, about 8 nm, about 9 nm, about 10 nm, about 11 nm, about 12 nm, about 13 nm, about 14 nm, about 15 nm, about 16 nm, about 17 nm, about 18 nm, about 19 nm, or about 20 nm thick, where any of the stated values can form an upper or lower endpoint of a range.

Alternatively, the catalyst can be deposited as particles on the carbon substrate or buffer.

For example, the catalyst can be deposited as particles that are from about 2 to about 20 nm in diameter, e.g., about 2 nm, about 3 nm, about 4 nm, about 5 nm, about 6 nm, about 7 nm, about 8 nm, about 9 nm, about 10 nm, about 11 nm, about 12 nm, about 13 nm, about 14 nm, about 15 nm, about 16 nm, about 17 nm, about 18 nm, about 19 nm, or about 20 nm in diameter, where any of the stated values can form an upper or lower endpoint of a range.

Once the buffer and catalyst are deposited on the carbon substrate, the substrate is contacted with a working gas, which comprises a hydrocarbon gas. Suitable examples of working gases are gases comprising ethylene, acetylene, methane, toluene, benzene or a combination thereof. In some examples, the working gas is flowed over the substrate at a rate of from about 1 to about 1000 sccm, e.g., about 1 sccm, about 50 sccm, about 100 sccm, about 150 sccm, about 200 sccm, about 250 sccm, about 300 sccm, about 350 sccm, about 400 sccm, about 450 sccm, about 500 sccm, about 550 sccm, about 600 sccm, about 650 sccm, about 700 sccm, about 750 sccm, about 800 sccm, about 850 sccm, about 900 sccm, about 950 sccm, or about 1000 sccm, where any of the stated values can form an upper or lower endpoint of a range. In a preferred example, the working gas is flowed over the carbon substrate at a rate of about 50 sccm.

The temperature of the working gas remains elevated and it can be flowed over the carbon substrate for from about 1 to about 60 minutes, or from about 10 to about 30 minutes, e.g., about 1 minutes, about 10 minutes, about 20 minutes, about 30 minutes, about 40 minutes, about 50 minutes, or about 60 minutes, where any of the stated values can form an upper or lower endpoint of a range.

The temperature at which the carbon substrate is contacted with the working gas is from about 400 to about 1100° C. For example, the temperature can be about 400° C., about 425° C., about 450° C., about 475° C., about 500° C., about 525° C., about 550° C., about 575° C., about 600° C., about 625° C., about 650° C., about 675° C., about 700° C., about 725° C., about 750° C., about 775° C., about 800° C., about 825° C., about 850° C., about 875° C., about 900° C., about 925° C., about 950° C., about 975° C., about 1000° C., about 1025° C., about 1050° C., about 1075° C., or about 1100° C., where any of the stated values can form an upper or lower endpoint of a range.

The result of this process is a “forest” of carbon nanotubes on the carbon substrate. The carbon nanotubes on the carbon substrate can be from about 1 to about 500 μm in length. For example, the carbon nanotubes can be 1 μm, about 50 μm, about 100 μm, about 150 μm, about 200 μm, about 250 μm, about 300 μm, about 350 μm, about 400 μm, about 450 μm, or about 500 μm in length, where any of the stated values can form an upper or lower endpoint of a range. In preferred examples, the carbon nanotubes can be from about 250 μm to about 500 μm in length. For example, the carbon nanotubes can be about 250 μm, about 275 μm, about 300 μm, about 325 μm, about 350 μm, about 375 μm, about 400 μm, about μm, about 450 μm, about 475 μm, or about 500 μm in length, where any of the stated values can form an upper or lower endpoint of a range.

The carbon nanotubes can be from about 1 to about 50 nm in diameter, e.g., about 1 nm, about 5 nm, about 10 nm, about 15 nm, about 20 nm, about 25 nm, about 30 nm, about 35 nm, about 40 nm, about 45 nm, or about 50 nm in diameter. In a preferred example, the carbon nanotubes are about 10 nm in diameter.

In some examples, the carbon nanotubes can comprise single walled nanotubes, double walled nanotubes, multi-walled nanotubes, or a combination thereof.

A composition comprising a conformal layer of carbon nanotubes on a porous carbon substrate is also disclosed. The carbon substrate can be selected from the group consisting of a carbon foam, a graphite foam, and a 3D printed graphite foam.

The thickness of the graphene walls in the carbon substrate can be varied, depending on how certain parameters are adjusted in the synthesis. For example, by using a nickel foam with thicker strut walls, increasing vapor deposition times, and increasing the concentration of carbon precursor can thicken the graphene walls of the carbon substrate. In general, the thickness of the walls of the carbon substrate can be from about 2 nm to about 500 nm in thickness, e.g., about 2, about 50 nm, about 100 nm, about 150 nm, about 200 nm, about 250 nm, about 300 nm, about 350 nm, about 400 nm, about 450 nm, or about 500 nm, wherein any of the stated values can form an upper or lower endpoint of a range.

As detailed more specifically above, the carbon nanotubes on the carbon substrate can be from about 1 to about 500 μm in length, from about 1 to about 50 nm in diameter, and can comprise single walled nanotubes, double walled nanotubes, multi-walled nanotubes, or combinations thereof.

A thermal composite comprising a layer of carbon nanotubes on a carbon substrate and a phase change material (PCM) is disclosed. A PCM is a substance with a high heat of fusion which, melting and solidifying at a certain temperature, is capable of storing and releasing large amounts of energy. Heat is absorbed or released when the material changes from solid to liquid and vice versa. For example, the PCM can be water, a salt-water solution, a sugar alcohol, a paraffin, a fatty acid, a salt hydrate, a nitrate, a hydroxide, a hygroscopic material, or combinations thereof. More specifically, the PCM can be erythritol; xylitol; mannitol; galactitol; a blend of galactitol and mannitol; urea; ureidopyrimidone; N,N-dialkylpiperidinum; N,N-dialkylpyrrolidinium; LiF and BeF₂; NaF and BeF₂; LiF and NaF and KF; NaF and ZrF₄; KNO₃ and KCl; KNO₃ and K₂CO₃; LiBr and KBr; KNO₃ and KBr; KNO₃ and LiOH; FeCl₂ and KCl; KCl and LiCl; K₂CO₃ and KOH; K₂SO₄ and KOH; FeCl₂ and NaCl; KCl and MnCl₂; LiBr and LiI; KCl—MgCl₂; MnCl₂ and NaCl; LiCO₃ and LiOH; LiBr and LiF; NaCl and MgCl₂; K₂CO₃ and MgCO₃; KF and KBF₄; Na₂SO₄ and ZnSO₄; CaCl₂ and LiCl; LiCl and Li₂SO₄; KF and LiF; K₂CO₃ and Li₂CO₃; Li₂CO₃ and Na₂CO₃; LiCl and LiF; CaCl₂ and NaCl; KVO₃ and BaTiO₃; KCl and LiBr and NaBr; KBr and LiCl and NaCl; LiBr and NaBr and KBr; NaOH and NaCl and Na₂CO₃; KCl and LiCl and Li₂SO₄; MgCl₂ and KCl and NaCl; NaCl and KCl and FeCl₂; KCl and LiCl and CaF₂; CaCl₂ and KCl and LiCl; NaCl and KCl and LiCl; KF and AlF₃ and ZrF₄; MnCl₂ and KCl and NaCl; Na₂SO₄ and K₂SO₄ and ZnSO₄; Na₂CO₃ and K₂CO₃ and ZnSO₄; Na₂CO₃ and K₂CO₃ and LiCO₃; KCl and NaCl and LiF; LiCl and NaCl and Li₂SO₄; LiCl and KCl and CaCl₂ and CaF₂; KCl and NaCl and LiCl and Li₂SO₄; NaNO₃; KNO₃; KNO₃ and KCl; KNO₃ and K₂CO₃; KNO₃ and KBr; FeCl₂ and KCl; KCl and LiCl; K₂CO₃ and KOH; K₂SO₄ and KOH; FeCl₂ and NaCl; LiBr and KBr; NaOH and NaCl and Na₂CO₃; MgCl₂ and KCl and NaCl; NaCl and KCl and FeCl₂; CaCl₂ and KCl and LiCl; MgCl₂ and KCl and NaCl; MgCl₂ and KCl and NaCl; NaOH and NaCl and Na₂CO₃; MnCl₂ and KCl and NaCl; Na₂CO₂ and K₂CO₃ and Li₂CO₃; LiF and LiCl and LiVO₃ and Li₂SO₄ and Li₂MoO₄; LiF and LiCl and Li₂SO₄ and Li₂MoO₄; LiF and KF and KCO₄ and KCl; LiF and LiOH; LiF and BaF₂ and KF and NaF; LiF and KF and NaF and KCl; LiF and NaF and KF and MgF₂; LiF and NaF and KF; LiF and KF and NaF; LiF and NaF and KF; LiF and LiCl; KF and LiCl; KF and LiCl; LiF and KF; LiF and LiVO₃ and Li₂MoO₄; LiCl and KCl and LiCO₃ and LiF; LiCl and KCl; KCl and MnCl₂ and NaCl; LiClLiVO₃ and Li₂MoO₄ and Li₂SO₄ and LiF; NaCl and KCl and MgCl₂; KCl and MgCl₂ and NaCl; NaCl and MgCl₂; KCl and ZnCl₂; KCl and MgCl₂; NaCl═MgCl₂; LiCl and Li₂SO₄ and Li₂MoO₄; KCl and MnCl₂; LiCl and Li₂SO₄ and LiVO₃; KCl and MnCl₂; NaCl and MgCl₂; CaCl₂ and KCl and NaCl and NaF; CaCl₂ and KCl and MgCl₂ and NaCl; CaCl₂ and KCl and NaCl; KCl and MgCl₂; LiCl and LiF and MgF₂; CaCl₂ and CaF₂ and NaF; CaCl₂ and NaCl; NaOH and NaCl and Na₂CO₃; LiOH and LiF; Li₂CO₃ and K₂CO₃ and Na₂CO₃; Li₂CO₃ and K₂CO₃; Li₂CO₃ and K₂CO₃; Zn and Mg; Al and Mg and Zn; Mg and Cu and Zn; Mg and Cu and Ca; Mg and Al; formic acid; caprilic acid; glycerin; D-Lactic acid; methyl palmitate; camphenilone; docasyl bromide; caprylone; phenol; heptadecanone; 1-cyclohexylooctadecane; 4-heptadacanone; p-joluidine; cyanamide; methyl eicosanate; 3-heptadecanone; 2-heptadecanone; hydrocinnamic acid; cetyl alcohol; α-nepthylamine; camphene; O-nitroaniline; 9-heptadecanone; thymol; sodium acetate; trimethylolethane; methylbehenate; diphenyl amine; p-dichlorobenzene; oxalate; hypophosphoric acid; O-xylene dichloride; β-chloroacetic acid; nitro naphthalene; trimyristin; heptaudecanoic acid; α-chloroacetic acid; bee wax; bees wax; glycolic acid; glyolic acid; p-bromophenol; azobenzene; acrylic acid; dinto toluent; phenylacetic acid; thiosinamine; bromcamphor; durene; benzylamine; methyl bromobenzoate; alpha napthol; glautaric acid; p-xylene dichloride; catechol; quinine; acetanilide; succinic anhydride; benzoic acid; stibene; benzamide; acetic acid; polyethylene glycol; capric acid; eladic acid; lauric acid; pentadecanoic acid; trustearin; myristic acid; palmatic acid; stearic acid; acetamide; methyl fumarate; K₂HPO₄.6H₂O; FeBr₃.6H₂O; Mn(NO₃)₂.6H₂O; FeBr₃.6H₂O; CaCl₂.12H₂O; LiNO₃.2H₂O; LiNO₃.3H₂O; Na₂CO₃.10H₂O; Na₂SO₄.10H₂O; KFe(SO₄)₂.12H₂O; CaBr₂.6H₂O; LiBr₂.2H₂O; Zn(NO₃)₂.6H₂O; FeCl₃.6H₂O; Mn(NO₃)₂.4H₂O; Na₂HPO₄.12H₂O; CoSO₄.7H₂O; KF.2H₂O; MgI₂.8H₂O; CaI₂.6H₂O; K₂HPO₄.7H₂O; Zn(NO₃)₂.4H₂O; Mg(NO₃).4H₂O; Ca(NO₃).4H₂O; Fe(NO₃)₃^{.}9H₂O; Na₂SiO₃.4H₂O; K₂HPO₄.3H₂O; Na₂S₂O₃.5H₂O; MgSO₄.7H₂O; Ca(NO₃)₂.3H₂O; Zn(NO₃)₂.2H₂O; FeCl₃.2H₂O; Ni(NO₃)₂.6H₂O; MnCl₂.4H₂O; MgCl₂.4H₂O; CH₃COONa.3H₂O; Fe(NO₃)₂.6H₂O; NaAl(SO₄)₂.10H₂O; NaOH.H₂O; Na₃PO₄.12H₂O; LiCH₃COO.2H₂O; Al(NO₃)₂.9H₂O; Ba(OH)₂.8H₂O; Mg(NO₃)₂.6H₂O; KAl(SO₄)₂.12H₂O; MgCl₂.6H₂O; gallium-gallium antimony eutectic; gallium; cerrolow eutectic; Bi—Cd—In eutectic; cerrobend eutectic; Bi—Pb—In eutectic; Bi—In eutectic; Bi—Pb-tin eutectic; Bi—Pb eutectic; CaCl₂.6H₂O and CaBr₂.6H₂O; Triethylolethane and water and urea; C₁₄H₂₈O₂ and C₁₀H₂₀O₂; CaCl₂ and MgCl₂.6H₂O; CH₃CONH₂ and NH₂CONH₂; Triethylolethane and urea; Ca(NO₃).4H₂O and Mg(NO₃)₃.6H₂O; CH₃COONa.3H₂O and NH₂CONH₂; NH₂CONH₂ and NH₄NO₃; Mg(NO₃)3.6H₂O and NH₄NO₃; Mg(NO₃)₃.6H₂O and MgCl₂.6H₂O; Mg(NO3)3.6H₂O and MgCl₂.6H₂O; Mg(NO3)3.6H₂O and Al(NO₃)₂.9H₂O; CH₃CONH₂ and C₁₇H₃₅COOH; Mg(NO₃)₂.6H₂O and MgBr₂.6H₂O; Napthalene and benzoic acid; NH₂CONH₂ and NH₄Br; LiNO₃ and NH₄NO₃ and NaNO₃; LiNO₃ and NH₄NO₃ and KNO₃; LiNO₃ and NH₄NO₃ and NH₄Cl; or combinations thereof.

In some examples, the melting temperature of the PCM can be from about minus 100° C. to about 400° C., e.g., about minus 100° C., about minus 50° C., about 0° C., about 50° C., about 100° C., about 150° C., about 200° C., about 250° C., about 300° C., about 350° C., or about 400° C., where any stated value and form an upper or lower endpoint of a range. The PCM can comprise a salt water solution with a melting temperature from about minus −100° C. to about 0° C. The PCM can be a paraffin with a melting temperature of from about 0° C. to about 150° C. The PCM can be a salt hydrate with a melting temperature of from about 50° C. to about 100° C. The PCM can be a sugar alcohol with a melting temperature of from about 50° C. to about 225° C. The PCM can be a nitrate with a melting temperature of from about 150° C. to about 300° C. The PCM can be a hydroxide with a melting temperature of from about 200° C. to about 400° C.

The melting enthalpy of the PCM can be from about 100 to about 700 MJ/m³. For example, the melting enthalpy can be about 100 MJ/m³, about 150 MJ/m³, about 200 MJ/m³, about 250 MJ/m³, about 300 MJ/m³, about 350 MJ/m³, about 400 MJ/m³, about 450 MJ/m³, about 500 MJ/m³, about 550 MJ/m³, about 600 MJ/m³, about 650 MJ/m³, or about 700 MJ/m³. In some examples, the PCM comprises a salt water solution with a melting enthalpy of from about 150 to about 300 MJ/m³. In other examples, the PCM is a paraffin with a melting enthalpy of from about 150 to about 200 MJ/m³. In other examples, the PCM is a salt hydrate with a melting enthalpy of from about 200 to about 600 MJ/m³. In other examples, the PCM is a sugar alcohol with a melting enthalpy of from about 200 to about 400 MJ/m³. In other examples, the PCM is a nitrate with a melting enthalpy of from about 200 to about 600 MJ/m³. In other examples, the PCM is a hydroxide with a melting enthalpy of from about 450 to about 700 MJ/m³.

One preferred PCM for use in the disclosed thermal composites comprises a blend of two sugar alcohols: galactitol and mannitol, as described herein more fully above.

The galactitol and mannitol blend can be the major component of the PCM. For example, the amount of the galactitol and mannitol blend can be at least about 75 wt. % of the total PCM. In other examples, the amount of galactitol and mannitol blend can be at least about 75, about 80, about 85, about 90, about 95, about 98, or about 99 wt. % of the total PCM, where any of the stated values can form an upper or lower endpoint of a range.

In a preferred example, the PCM comprises galactitol and mannitol in a weight ratio of about 1:1, has a melting point of about 151 to about 153° C., and a latent heat of fusion of from about 300 J/g to about 310 J/g.

The PCM can optionally comprise one or more additives. Examples of suitable additives include viscosity modifiers, antimicrobial agents, fire retardants, agents to prevent supercooling, thickeners, antioxidants, corrosion inhibitors and combinations thereof. The disclosed PCMs can also be microencapsulated.

Three dimensional (3D) printing is a process of making a three-dimensional solid object using an additive process, where successive layers of material are laid down in different shapes to form the ultimate 3D object. Both polymers and metals for example can now be printed using a variety of techniques, although the metals used are limited to a handful of popular alloys such as Cu and Ni.

Graphitic matrixes can be produced with 3D printing processes to form templates that are subsequently graphitized to yield a 3D printed graphitic matrix. The thus produced graphitic matrixes could be used as the substrates for subsequent carbon nanotube formation, and the resultant material could be used in heat exchangers, thermal storage apparatus' such as thermal batteries, electrochemical storage and exchange devices such as lithium ion batteries, and other potentially useful applications. The templates used to produce the graphitic matrixes can be printed metal templates such as nickel templates or printed graphitizable polymer templates. The structure patterns of the template are based on a digital model that has geometries that can be individually designed for a specific application, i.e. rationally designed. For example, the 3D graphitic matrix can be designed to have a structure pattern that is in accordance with natural path of thermal transmission. The template is subsequently graphitized through pyrolysis of the graphitizable polymers or using high temperature chemical vapor deposition (CVD) to produce 3D printed graphitic matrixes that possess the same 3D structure pattern as the template. The graphitization of the polymer template produces the 3D graphitic matrixes directly from the template. When the template is a metal template, the underlying metal is etched away once the 3D graphitic matrixes are formed.

The disclosed carbon foam/carbon nanotube hybrid materials, and thermal composites including them, are suitable for use in thermal controllers for reactors or thermal energy storage devices. One particular device contemplated herein is a thermal battery, as described herein more fully elsewhere.

The thermal storage units can comprise a heat exchange path through which a heat exchange medium flows, and a thermal storage medium in thermal contact with the heat exchange path. The thermal storage medium can comprise a composite formed from a porous thermally conductive matrix and a phase change material (PCM) disposed within the porous thermally conductive matrix. The thermally conductive matrix can comprise a metal foam, a carbon- or graphite-containing metal foam, a graphite foam, a carbon foam, a 3D-printed graphite matrix, or combinations thereof. Optionally, the thermally conductive matrix can further comprise a layer of carbon nanotubes disposed on the graphite foam, the carbon foam, the 3D-printed graphite matrix, the metal foam, or combinations thereof, such as those disclosed herein. The PCM can be any suitable PCM. In some embodiments, the PCM comprises a PCM having a melting temperature of from about 50° C. to about 225° C., a melting enthalpy of from about 200 MJ/m³ to about 400 MJ/m³, or combinations thereof. In certain embodiments, the PCM comprises a sugar alcohol or a blend of sugar alcohols (e.g., a blend of mannitol and galactitol).

Methods of use of the materials disclosed herein are also disclosed. In some embodiments, the material is used as a thermal conductivity substrate for flexible graphene devices. In some examples, the material is used as an electrode in a battery. In some examples, the material is used in a thermal storage device. In some examples, the material is used in a heat exchange device. In some examples, the material is used with a phase change material in a thermal storage unit, for example as described herein more fully below.

### Graphitic Matrixes

Ultra thin graphite foam has been reported to have very high thermal conductivity, large surface to volume ratio, and has been successfully used in thermal storage and electrochemical battery applications (Ji et al. Nano Lett. 2012, 12, 2446-2451; Pettes et al. Nano Lett. 2012, 12, 2959-2964). The graphite foam comprises three dimensional interconnected graphite structures that are highly conductive. When the pores of the foam are filled with an active material, such as a phase change material for thermal exchange or storage applications, or filled with an electrochemically active material, such as lithium metal oxide or lithium iron phosphate for electrochemical applications, the three dimensional interconnected graphite structures can efficiently transport heat and charge from the active materials embedded in the pores of the graphite foam. The three dimensional interconnected graphite structures of the graphite foam provide a three dimensional matrix of pores surrounded by interconnected walls. These interconnected walls of the graphite foam can be further modified by introducing carbon nanomaterials into the pores of the matrix. Carbon nanotubes, for example, can be grown on the walls and inside the pores of the graphite foam to provide graphitic materials, as described more fully herein above.

Three dimensional (3D) printing is a process of making a three-dimensional solid object using an additive process, where successive layers of material are laid down in different shapes to form the ultimate 3D object. Since the first working 3D printer was created in 1984 by Chuck Hull of 3D Systems Corp., 3D printing technology has been applied in architecture, construction (AEC), industrial design, automotive, aerospace, military, engineering, civil engineering, dental and medical industries, biotech (human tissue replacement), fashion, footwear, jewelry, eyewear, education, geographic information systems, food, and many other fields. Both polymers and metals, for example metal alloys such as Ni containing alloys, can be printed using a variety of techniques.

Three dimensional (3D) graphitic matrixes are disclosed herein. The 3D graphitic matrixes can, for example, feature high quality continuous graphitic materials that can, in some examples, have efficient thermal and electrical properties. The graphitic matrixes can be produced with 3D printing processes. For examples, 3D printing can be used to form templates that are subsequently graphitized to yield a 3D printed graphitic matrix. 3D-printed graphitic matrixes are graphitic materials formed using a 3D printed template. 3D-printing can provide precise control over the morphology of the graphitic material. Accordingly, 3D-printed graphitic matrixes can possess a structure comprising a microporous network formed of continuous graphitic material. The graphitic matrixes can be used, for example, in heat exchangers, thermal storage apparatus' such as thermal batteries, electrochemical storage and exchange devices such as lithium ion batteries, among other applications.

The 3D-printed graphitic matrix can be formed so as to possess any suitable morphology. Methods for preparing 3D-printed graphitic matrixes can comprise forming a microporous template using a 3D-printing processes, and graphitizing the microporous template to yield a 3D-printed graphitic matrix. The microporous template can be formed from any suitable graphitizable material which can be printed using standard 3-D printing methods. For example, the microporous template can be a metal template (e.g., a nickel template) or a graphitizable polymer template. Metal (e.g., Ni) templates can be formed via Direct Metal Laser Sintering (DMLS) of metal (e.g., Ni) powders. DMLS uses a small diameter laser to sinter metal powders to form a metallurgic bond. The laser path is controllable and by continually adding more layers of metal powder, a microporous metal template can be printed based on a digital model. A variety of 3D-printing processes, including stereolithography and selective laser sintering, can be used to form microporous polymer templates. The structure of the template can be individually designed for a specific application, i.e., rationally designed. For example, the 3D graphitic matrix can be designed to have a structure that corresponds to a desired path for thermal transmission.

Once formed using 3-D printing methods, the microporous template can be graphitized. Methods for graphitizing the matrix can vary depending upon a number of factors, including the composition of the microporous template. Metal templates (e.g., Ni templates) can be graphitized using high temperature chemical vapor deposition (CVD) to form a graphite matrix on the surface of the metal template. Once the graphite matrix has been formed, the metal template can be etched away, as described above. Templates formed from a graphitizable polymer can graphitized through pyrolysis of the graphitizable polymer. This process can form a 3D-graphitic matrix directly from the microporous template. Polymer templates can also be graphitized by metalizing the polymer template, and then graphitizing the metalized polymer template using the methods described above for graphitizing metal templates.

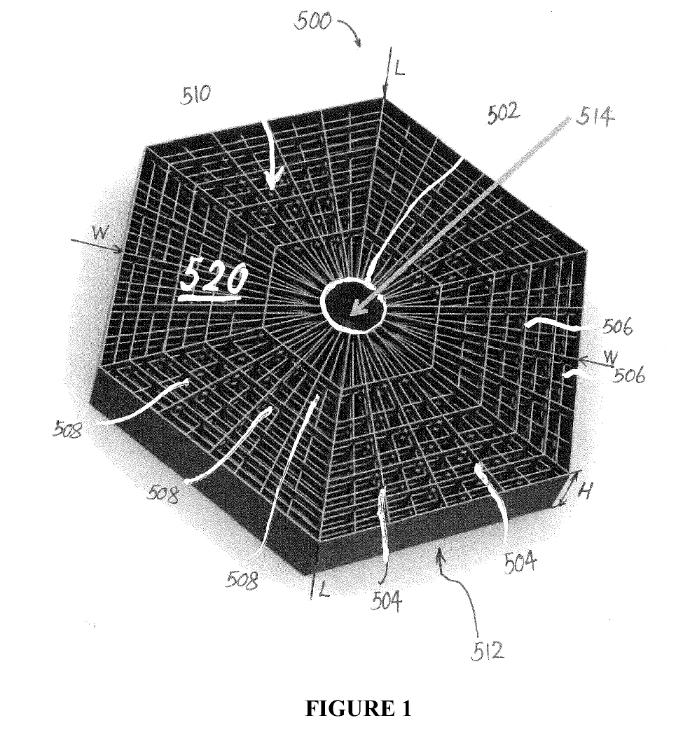

In some embodiments, the 3D-printed graphitic matrix can be fabricated as shown in FIG. 1. The 3D-printed graphitic matrix (500) can comprise a hub (502), a plurality of radius thin walls (504) radiating from the hub (502), and a plurality circumferential thin walls (506) concentrically surrounding the hub (502) and intersecting with the radius thin walls (504) to form a matrix (520) having a plurality of pores (508) within the matrix. The 3D-printed graphitic matrix (500) can have a top surface (510) and a bottom surface (512). The radius thin walls (504) and the circumferential thin walls (506) can be substantially perpendicular to the top surface (510) and the bottom surface (512). The pores (508) can be open to both the top surface (510) and the bottom surface (512). The hub (502) can comprise a cylindrical opening (514) which can pass through the center of the 3D-printed graphitic matrix (500) from the top surface (510) to the bottom surface (512). The hub (502), the circumferential thin walls (506), and the radius thin walls (504) can comprise graphitic carbon. The 3D-printed graphitic matrix (500) can be a hexagon with equal edges having a height H, a width W, and a length L.

In some embodiments, the cylindrical opening (514) can have a radius ranging from greater than about 0 mm to about 15 mm (e.g. 0-1 mm, 1-2 mm, 2-3 mm, 3-4 mm, 4-5 mm, 5-7 mm, 7-9 mm, 9-11 mm, 11-13 mm, 13-15 mm, or any combinations of these ranges). In some embodiments, the cylindrical opening (514) can have a radius of from about 1.5 mm to about 6.5 mm (e.g. 1.5-2 mm, 2-2.5 mm, 2.5-3 mm, 3-3.5 mm, 3.5-4 mm, 4-4.5 mm, 4.5-5 mm, 5-5.5 mm, 5.5-6 mm, 6-6.5 mm, or any combinations of these ranges). The circumferential thin walls (506) and the radius thin walls (504) can have a thickness of from about 0.01 μm to about 1μm (e.g. 0.01-0.05 μm, 0.05-0.1 μm, 0.1-0.15 μm, 0.15-0.2 μm, 0.2-0.25 μm, 0.25-0.3 μm, 0.3-0.35 μm, 0.35-0.4 μm, 0.4-0.45 μm, 0.45-0.5 μm, 0.5-0.55 μm, 0.55-0.6 μm, 0.6-0.65 μm, 0.65-0.7 μm, 0.7-0.75 μm, 0.75-0.8 μm, 0.8-0.85 μm, 0.85-0.9 μm, 0.9-0.95 μm, 0.95-1 μm, or any combinations of these ranges). In some embodiments, the pores (508) can have an average pore size, measured as the largest cross-sectional dimension of the pores, of from 100 μm to 5000 μm (e.g. 100-200 μm, 200-300 μm, 300-400 μm, 400-500 μm, 500-750 μm, 750-1000 μm, 1000-1250 μm, 1250-1500 μm, 1500-1750 μm, 1750-2000 μm, 2000-2500 μm, 2500-3000 μm, 3000-3500 μm, 3500-4000 μm, 4000-4500 μm, 4500-5000 μm, or any combinations of these ranges). The height (H) of the 3D-printed graphitic matrix can be from 0.2 mm to 100 mm (e.g. 0.2-1 mm, 1-5 mm, 5-10 mm, 10-20 mm, 20-30 mm, 30-40 mm, 40-50 mm, 50-75 mm, 75-1000 mm, or any combinations of these ranges). The 3D-printed graphitic matrix can have a width, a length, or a diameter from 5 mm to 500 mm (e.g. 5-10 mm, 10-20 mm, 20-40 mm, 40-60 mm, 60-100 mm, 100-150 mm, 150-200 mm, 200-250 mm, 250-300 mm, 300-350 mm, 350-400 mm, 400-450 mm, 450-500 mm or any combinations of these ranges).

Although a specific radial and circumferential designed pattern is illustrated in FIG. 1, other similarly tailored microporous structures can be produced. In some embodiments, the graphitic matrix can have a structure that can comprise a first plurality of thin walls and a second plurality of thin walls intersecting with the first plurality of thin walls to form a matrix comprising a plurality of pores, wherein the structure comprises graphitic carbon.

In some embodiments, the graphitic matrix does not have a cylindrical opening.

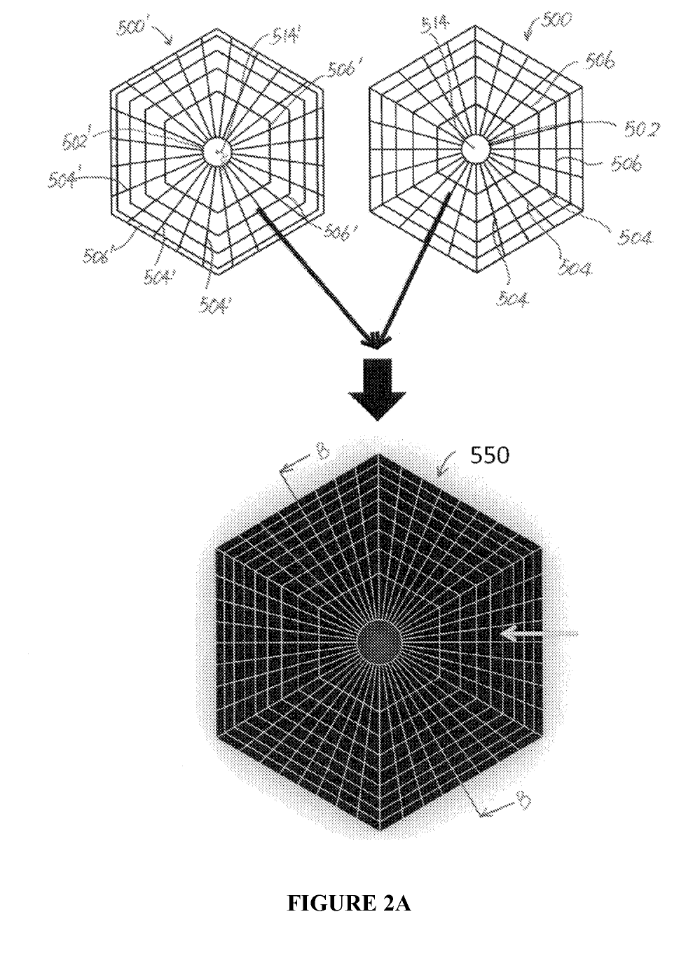

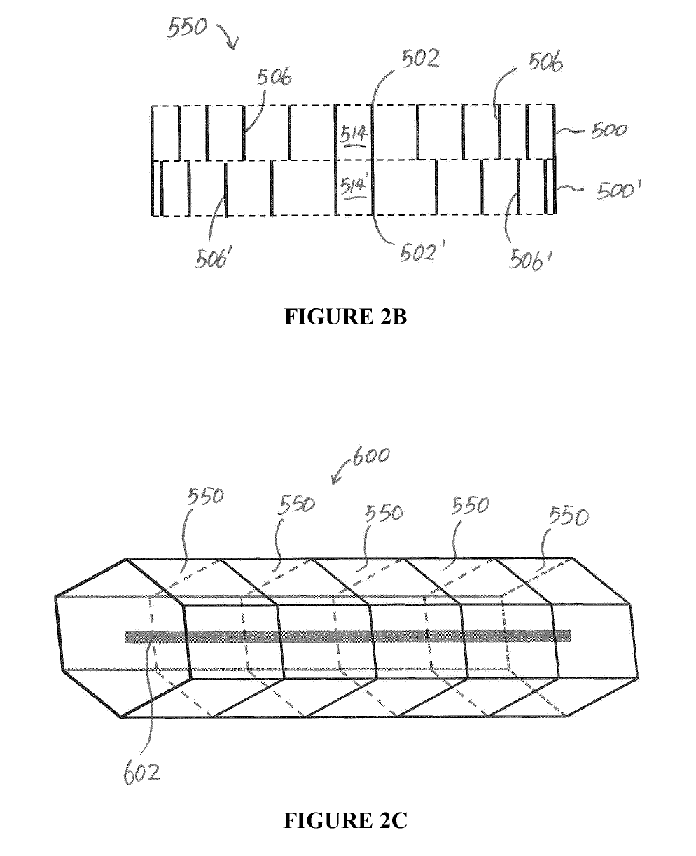

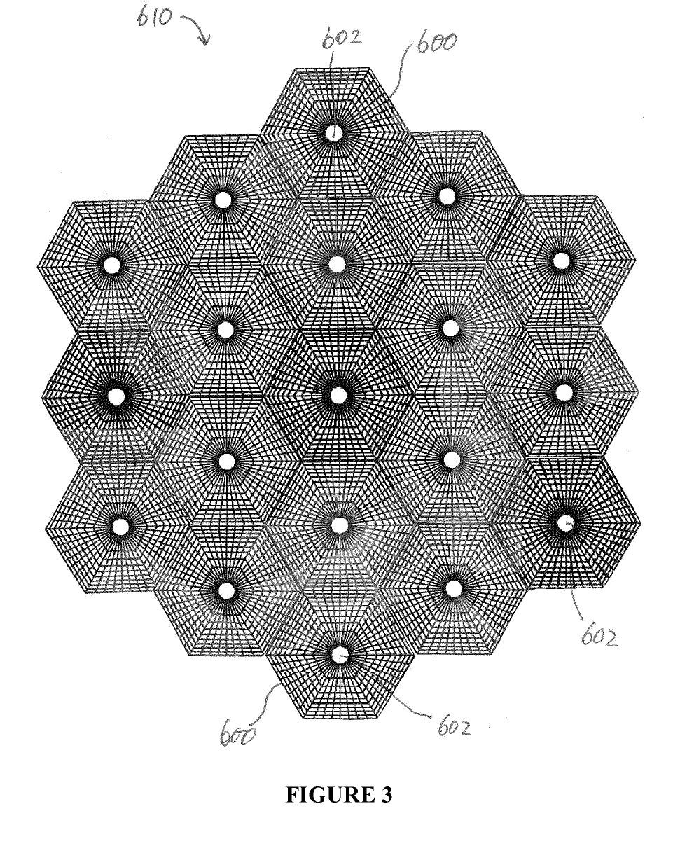

FIG. 2A displays a schematic diagram of an examplary process of stacking two matrix units (500) and (500′) with their respective thin walls offset (504 vs. 504′, 506 vs. 506′) to produce a graphitic matrix (550). A top view of units (500) and (500′) and matrix (550) are shown in FIG. 2A. The porous graphitic matrix units (500) and (500′) can, for example, both be hexagonal in shape and have hubs (502) and (502′), respectively. In some embodiments, hubs (502) and (502′) can be the same size. In some embodiments, hubs (502) and (502′) can be at the same relative position in units (500) and (500′). In some examples, hubs (502) and (502′) can have cylindrical openings (514) and (514′), respectively. In some embodiments, cylindrical openings (514) and (514′) can be the same size. In some embodiments, cylindrical openings (514) and (514′) can be at the same relative position in hubs (502) and (502′). In some embodiments, the radius walls (504) of unit (500) can radiate at different angles from hub (502) compared to angles that the radius walls (504′) of unit (500′) radiate from hub (502′). In some embodiments, the circumferential walls (506) of unit (500) are placed at different distancees from hub (502) compared to the distances that the circumferential walls (506′) of unit (500′) are places from hub (502′). In some embodiments, when units (500) and (500′) are stacked on top of each other, the differently positioned walls (504), (504′), (506), and (506′) are offset from each other while the outermost edges and hubs (502) and (502′) of units (500) and (500′) are aligned to produce the integrated graphitic matrix (550). The cross sectional view of the matrix (550) along line B-B is illustrated in FIG. 2B. Unit (500) is shown stacked on top of unit (500′) and the cylindrical openings (514) and (514′) are shown aligned with each other with the circumferential side walls (506) and (506′) offset from each other in FIG. 2B. Although FIG. 2A and FIG. 2B only illustrated two units vertically stacked units, in some examples a plurality of units can be vertically stacked and aligned, such that the cylindrical openings of the units form a conduit to allow a tube to go through. Referring to FIG. 2C, a few matrixes (550) are stacked together to form a porous graphitic matrix (600) with the cylindrical openings of the units (550) forming a conduit (602). Although units with offset thin walls are shown to be stacked together in FIG. 2A-2C, in some embodiments, the units used to construct the matrix do not have to have offset thin walls. For example, units have exactly the same sets of walls can be stacked together to form a porous matrix having aligned thin walls and aligned pores. Units having any 3D printable structure can be used and, in some examples, combined to form the graphitic matrix and thus can produce graphitic matrixes having a variety of structure patterns.

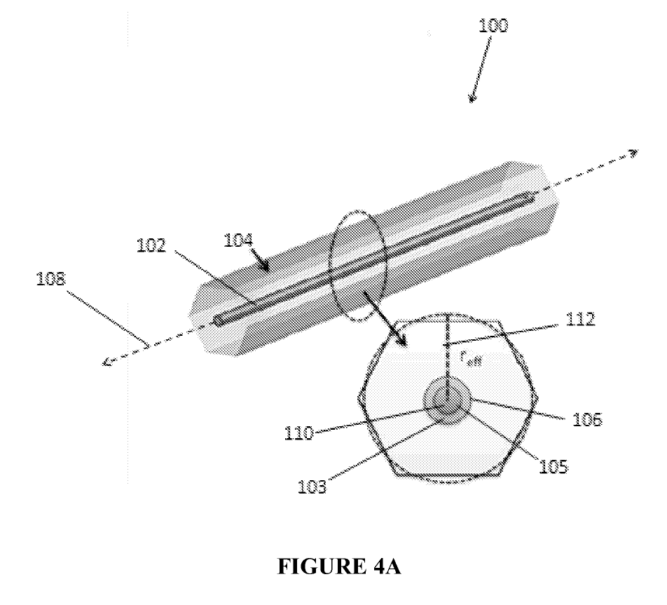

Referring now to FIG. 3, a schematic diagram of a graphitic matrix bundle (610) is illustrated. Nineteen matrixes (600) are arranged in an extended hexagonal pattern to form bundle (610). The conduits (602) of graphitic matrix bundle (600) are shown to be parallel to each other in this arrangement.

In some examples, the graphitic matrix can be further modified with carbon nanomaterials. For example, carbon nanotubes can be formed on the graphitic matrix to form a complex graphitic matrix. A method of forming carbon nanotubes on a graphitic matrix unit can comprise depositing a buffer layer on the graphitic matrix by atomic layer deposition; depositing a catalyst on the graphitic matrix or buffer layer; and contacting the graphitic matrix with a working gas at an elevated temperature to thereby form carbon nanotubes on the graphitic matrix, as described herein more fully above.

A thermal composite comprising a graphitic matrix and a phase change material (PCM) is also disclosed herein. A PCM is a substance with a high heat of fusion which, melting and solidifying at a certain temperature, is capable of storing and releasing large amounts of energy. Heat is absorbed or released when the material changes from solid to liquid and vice versa. For example, the PCM can be water, a salt-water solution, a sugar alcohol, a paraffin, a fatty acid, a salt hydrate, a nitrate, a hydroxide, a hygroscopic material, or combinations thereof. More specifically, the PCM can be erythritol; xylitol; mannitol; galactitol; a blend of galactitol and mannitol; urea; ureidopyrimidone; N,N-dialkylpiperidinum; N,N-dialkylpyrrolidinium; LiF and BeF₂; NaF and BeF₂; LiF and NaF and KF; NaF and ZrF₄; KNO₃ and KCl; KNO₃ and K₂CO₃; LiBr and KBr; KNO₃ and KBr; KNO₃ and LiOH; FeCl₂ and KCl; KCl and LiCl; K₂CO₃ and KOH; K₂SO₄ and KOH; FeCl₂ and NaCl; KCl and MnCl₂; LiBr and LiI; KCl═MgCl₂; MnCl₂ and NaCl; LiCO₃ and LiOH; LiBr and LiF; NaCl and MgCl₂; K₂CO₃ and MgCO₃; KF and KBF₄; Na₂SO₄ and ZnSO₄; CaCl₂ and LiCl; LiCl and Li₂SO₄; KF and LiF; K₂CO₃ and Li₂CO₃; Li₂CO₃ and Na₂CO₃; LiCl and LiF; CaCl₂ and NaCl; KVO₃ and BaTiO₃; KCl and LiBr and NaBr; KBr and LiCl and NaCl; LiBr and NaBr and KBr; NaOH and NaCl and Na₂CO₃; KCl and LiCl and Li₂SO₄; MgCl₂ and KCl and NaCl; NaCl and KCl and FeCl₂; KCl and LiCl and CaF₂; CaCl₂ and KCl and LiCl; NaCl and KCl and LiCl; KF and AlF₃ and ZrF₄; MnCl₂ and KCl and NaCl; Na₂SO₄ and K₂SO₄ and ZnSO₄; Na₂CO₃ and K₂CO₃ and ZnSO₄; Na₂CO₃ and K₂CO₃ and LiCO₃; KCl and NaCl and LiF; LiCl and NaCl and Li₂SO₄; LiCl and KCl and CaCl₂ and CaF₂; KCl and NaCl and LiCl and Li₂SO₄; NaNO₃; KNO₃; KNO₃ and KCl; KNO₃ and K₂CO₃; KNO₃ and KBr; FeCl₂ and KCl; KCl and LiCl; K₂CO₃ and KOH; K₂SO₄ and KOH; FeCl₂ and NaCl; LiBr and KBr; NaOH and NaCl and Na₂CO₃; MgCl₂ and KCl and NaCl; NaCl and KCl and FeCl₂; CaCl₂ and KCl and LiCl; MgCl₂ and KCl and NaCl; MgCl₂ and KCl and NaCl; NaOH and NaCl and Na₂CO₃; MnCl₂ and KCl and NaCl; Na₂CO₂ and K₂CO₃ and Li₂CO_{3;} LiF and LiCl and LiVO₃ and Li₂SO₄ and Li₂MoO₄; LiF and LiCl and Li₂SO₄ and Li₂MoO₄; LiF and KF and KCO₄ and KCl; LiF and LiOH; LiF and BaF₂ and KF and NaF; LiF and KF and NaF and KCl; LiF and NaF and KF and MgF₂; LiF and NaF and KF; LiF and KF and NaF; LiF and NaF and KF; LiF and LiCl; KF and LiCl; KF and LiCl; LiF and KF; LiF and LiVO₃ and Li₂MoO₄; LiCl and KCl and LiCO₃ and LiF; LiCl and KCl; KCl and MnCl₂ and NaCl; LiClLiVO₃ and Li₂MoO₄ and Li₂SO₄ and LiF; NaCl and KCl and MgCl₂; KCl and MgCl₂ and NaCl; NaCl and MgCl₂; KCl and ZnCl₂; KCl and MgCl₂; NaCl═MgCl₂; LiCl and Li₂SO₄ and Li₂MoO₄; KCl and MnCl₂; LiCl and Li₂SO₄ and LiVO₃; KCl and MnCl₂; NaCl and MgCl₂; CaCl₂ and KCl and NaCl and NaF; CaCl₂ and KCl and MgCl₂ and NaCl; CaCl₂ and KCl and NaCl; KCl and MgCl₂; LiCl and LiF and MgF₂; CaCl₂ and CaF₂ and NaF; CaCl₂ and NaCl; NaOH and NaCl and Na₂CO₃; LiOH and LiF; Li₂CO₃ and K₂CO₃ and Na₂CO₃; Li₂CO₃ and K₂CO₃; Li₂CO₃ and K₂CO₃; Zn and Mg; Al and Mg and Zn; Mg and Cu and Zn; Mg and Cu and Ca; Mg and Al; formic acid; caprilic acid; glycerin; D-Lactic acid; methyl palmitate; camphenilone; docasyl bromide; caprylone; phenol; heptadecanone; 1-cyclohexylooctadecane; 4-heptadacanone; p-joluidine; cyanamide; methyl eicosanate; 3-heptadecanone; 2-heptadecanone; hydrocinnamic acid; cetyl alcohol; α-nepthylamine; camphene; O-nitroaniline; 9-heptadecanone; thymol; sodium acetate; trimethylolethane; methylbehenate; diphenyl amine; p-dichlorobenzene; oxalate; hypophosphoric acid; O-xylene dichloride; β-chloroacetic acid; nitro naphthalene; trimyristin; heptaudecanoic acid; α-chloroacetic acid; bee wax; bees wax; glycolic acid; glyolic acid; p-bromophenol; azobenzene; acrylic acid; dinto toluent; phenylacetic acid; thiosinamine; bromcamphor; durene; benzylamine; methyl bromobenzoate; alpha napthol; glautaric acid; p-xylene dichloride; catechol; quinine; acetanilide; succinic anhydride; benzoic acid; stibene; benzamide; acetic acid; polyethylene glycol; capric acid; eladic acid; lauric acid; pentadecanoic acid; trustearin; myristic acid; palmatic acid; stearic acid; acetamide; methyl fumarate; K₂HPO₄.6H₂O; FeBr₃.6H₂O; Mn(NO₃)₂.6H₂O; FeBr₃.6H₂O; CaCl₂.12H₂O; LiNO₃.2H₂O; LiNO₃.3H₂O; Na₂CO₃.10H₂O; Na₂SO₄.10H₂O; KFe(SO₄)₂.12H₂O; CaBr₂.6H₂O; LiBr₂.2H₂O; Zn(NO₃)₂.6H₂O; FeCl₃.6H₂O; Mn(NO₃)₂.4H₂O; Na₂HPO₄.12H₂O; CoSO₄.7H₂O; KF.2H₂O; MgI₂.8H₂O; CaI₂.6H₂O; K₂HPO₄.7H₂O; Zn(NO₃)₂.4H₂O; Mg(NO₃).4H₂O; Ca(NO₃).4H₂O; Fe(NO₃)₃.9H₂O; Na₂SiO₃.4H₂O; K₂HPO₄.3H₂O; Na₂S₂O₃.5H₂O; MgSO₄.7H₂O; Ca(NO₃)₂.3H₂O; Zn(NO₃)₂.2H₂O; FeCl₃.2H₂O; Ni(NO₃)₂.6H₂O; MnCl₂.4H₂O; MgCl₂.4H₂O; CH₃COONa.3H₂O; Fe(NO₃)₂.6H₂O; NaAl(SO₄)₂.10H₂O; NaOH.H₂O; Na₃PO₄.12H₂O; LiCH₃COO.2H₂O; Al(NO₃)₂.9H₂O; Ba(OH)₂.8H₂O; Mg(NO₃)₂.6H₂O; KAl(SO₄)₂.12H₂O; MgCl₂.6H₂O; gallium-gallium antimony eutectic; gallium; cerrolow eutectic; Bi—Cd—In eutectic; cerrobend eutectic; Bi—Pb—In eutectic; Bi—In eutectic; Bi—Pb-tin eutectic; Bi—Pb eutectic; CaCl₂.6H₂O and CaBr₂.6H₂O; Triethylolethane and water and urea; C₁₄H₂₈O₂ and C₁₀H₂₀O₂; CaCl₂ and MgCl₂.6H₂O; CH₃CONH₂ and NH₂CONH₂; Triethylolethane and urea; Ca(NO₃).4H₂O and Mg(NO₃)₃.6H₂O; CH₃COONa.3H₂O and NH₂CONH₂; NH₂CONH₂ and NH₄NO₃; Mg(NO₃)3.6H₂O and NH₄NO₃; Mg(NO₃)₃.6H₂O and MgCl₂.6H₂O; Mg(NO3)3.6H₂O and MgCl₂.6H₂O; Mg(NO3)3.6H₂O and Al(NO₃)₂.9H₂O; CH₃CONH₂ and C₁₇H₃₅COOH; Mg(NO₃)₂.6H₂O and MgBr₂.6H₂O; Napthalene and benzoic acid; NH₂CONH₂ and NH₄Br; LiNO₃ and NH₄NO₃ and NaNO₃; LiNO₃ and NH₄NO₃ and KNO₃; LiNO₃ and NH₄NO₃ and NH₄Cl; or combinations thereof.

In some examples, the melting temperature of the PCM can be from about minus 100° C. to about 400° C., e.g., about minus 100° C., about minus 50° C., about 0° C., about 50° C., about 100° C., about 150° C., about 200° C., about 250° C., about 300° C., about 350° C., or about 400° C., where any stated value and form an upper or lower endpoint of a range. The PCM can comprise a salt water solution with a melting temperature from about minus −100° C. to about 0° C. The PCM can be a paraffin with a melting temperature of from about 0° C. to about 150° C. The PCM can be a salt hydrate with a melting temperature of from about 50° C. to about 100° C. The PCM can be a sugar alcohol with a melting temperature of from about 50° C. to about 225° C. The PCM can be a nitrate with a melting temperature of from about 150° C. to about 300° C. The PCM can be a hydroxide with a melting temperature of from about 200° C. to about 400° C.

The melting enthalpy of the PCM can be from about 100 to about 700 MJ/m³. For example, the melting enthalpy can be about 100 MJ/m³, about 150 MJ/m³, about 200 MJ/m³, about 250 MJ/m³, about 300 MJ/m³, about 350 MJ/m³, about 400 MJ/m³, about 450 MJ/m³, about 500 MJ/m³, about 550 MJ/m³, about 600 MJ/m³, about 650 MJ/m³, or about 700 MJ/m³. In some examples, the PCM comprises a salt water solution with a melting enthalpy of from about 150 to about 300 MJ/m³. In other examples, the PCM is a paraffin with a melting enthalpy of from about 150 to about 200 MJ/m³. In other examples, the PCM is a salt hydrate with a melting enthalpy of from about 200 to about 600 MJ/m³. In other examples, the PCM is a sugar alcohol with a melting enthalpy of from about 200 to about 400 MJ/m³. In other examples, the PCM is a nitrate with a melting enthalpy of from about 200 to about 600 MJ/m³. In other examples, the PCM is a hydroxide with a melting enthalpy of from about 450 to about 700 MJ/m³.

One preferred PCM for use in the disclosed thermal composites comprises a blend of two sugar alcohols: galactitol and mannitol, as described herein more fully above.

The galactitol and mannitol blend can be the major component of the PCM. For example, the amount of the galactitol and mannitol blend can be at least about 75 wt. % of the total PCM. In other examples, the amount of galactitol and mannitol blend can be at least about 75, about 80, about 85, about 90, about 95, about 98, or about 99 wt. % of the total PCM, where any of the stated values can form an upper or lower endpoint of a range.

In a preferred example, the PCM comprises galactitol and mannitol in a weight ratio of about 1:1, has a melting point of about 151 to about 153° C., and a latent heat of fusion of from about 300 J/g to about 310 J/g.

The PCM can optionally comprise one or more additives. Examples of suitable additives include viscosity modifiers, antimicrobial agents, fire retardants, agents to prevent supercooling, thickeners, antioxidants, corrosion inhibitors and combinations thereof. The disclosed PCMs can also be microencapsulated.

The disclosed graphitic matrixes, and thermal composites including them, are suitable for use in thermal controllers for reactors or thermal energy storage devices. One particular device contemplated herein is a thermal battery, as described herein more fully elsewhere.

Methods of use of the graphitic matrixes disclosed herein are also disclosed. In some examples, the graphitic matrix is used as an electrode in a battery. In some examples, the graphitic matrix is used in a thermal storage device. In some examples, the graphitic matrix is used in a heat exchange device. In some examples, the graphitic matrix is used with a phase change material in a thermal storage unit, for example as described herein more fully below.

In some examples, the graphitic matrixes describe herein can be used in thermal exchange devices and/or thermal storage devices. In some examples, the thermal exchange/storage devices using the graphitic matrix described herein can be used in applications where the storage of thermal energy is desirable. For example, the thermal storage units can be used to collect thermal energy for later use (e.g., hours, days or many months later). In this way, the thermal storage units can be used to improve energy efficiency in a wide variety of applications. For example, the thermal storage/exchange units described herein can be utilized in conjunction with heating and/or cooling systems (e.g., in conjunction with HVAC systems in vehicles such as cars and airplanes as well as in buildings), in conjunction with solar energy collection and utilization, in conjunction with refrigeration, or in conjunction with industrial processes. The thermal exchange/storage units described herein can be tailored for use in particular applications (e.g., for operation in various ranges of powers/energies) by adjusting the materials incorporated in the thermal storage unit to provide a thermal storage unit configured to operate in conjunction with different temperature regimes (e.g. by choosing a suitable PCM).

By way of example, the thermal exchange/storage units described herein can be incorporated into HVAC systems in vehicles, such as electric vehicles (EVs). Thermal exchange/storage units can be use to provide a low cost heating and cooling system to provide climate conditioning to an EV's cabin through stored thermal energy rather than energy from the Li-ion battery. In this way the driving range and efficiency of EVs can be improved. An example system for use in EVs can include two thermal storage units, referred to as the hot thermal battery and the cold thermal battery, each containing a different PCM. A heat transfer fluid (HTF) can be circulated between a cabin air heat exchanger and either thermal battery depending on operation mode (e.g., heating or cooling of the cabin air). Heating can be achieved through solidification of a high temperature PCM present in the hot thermal battery and cooling can be achieved through melting of a low temperature PCM in the cold thermal battery. The thermal batteries can be recharged by circulating the HTF through an off-board charge station configured to provide or extract the heat needed for reversing the phase change process within the batteries while the EV's Li-ion battery is charging. The charge station can be configured such that the charge time for recharging the thermal batteries is less than the charge time for recharging the Li-ion battery charge time.

In electrochemical applications such as lithium ion batteries, electrochemically active material can be embedded inside the pores of the graphitic matrix. The graphitic matrix servers as current collector that could collect charge from the active material and transmit the collected charge to another electrode. The graphitic matrix can be used in anode and cathode or both in a battery. In lithium ion batteries for example, graphitic matrix used as a current collector can replace the traditional metal current collectors such as aluminum or copper current collector. Due to its light weight, stability, and much larger surface area compared to a metal current collector, use of the graphitic matrix current collector produce lighter batteries that have higher energy density compared to batteries with traditional metal collectors. Because of its stability, graphitic matrixes for example are compatible with lithium metal oxide and lithium iron phosphate as cathode materials. Although in most Li-ion batteries, the anode is graphite (Goodenough and Kim. Chem. Mater. 2010, 22, 587-603; Hayner et al. Annu. Rev. Chem. Biomol. Eng. 2012, 3, 445-471). Silicon has been explored as an alternative anode material but has limited utility due to its significant volume expansion upon lithium uptake. The high porosity of the graphitic matrix disclosed herein can accommodate the volume expansion produced by silicon and be used as a current collector for silicon based anode active materials to further improve the capacity of a battery.

### Thermal Storage Units

Also disclosed herein are thermal storage units. The thermal storage units can comprise a heat exchange path through which a heat exchange medium flows, and a thermal storage medium in thermal contact with the heat exchange path. The thermal storage medium can comprise a composite formed from a porous thermally conductive matrix and a phase change material (PCM) disposed within the porous thermally conductive matrix. The thermal storage units can be used to provide and/or absorb thermal energy, depending on the melting temperature disposed within the porous thermally conductive matrix relative to the ambient or process temperature (e.g., the temperature of the heat exchange medium).

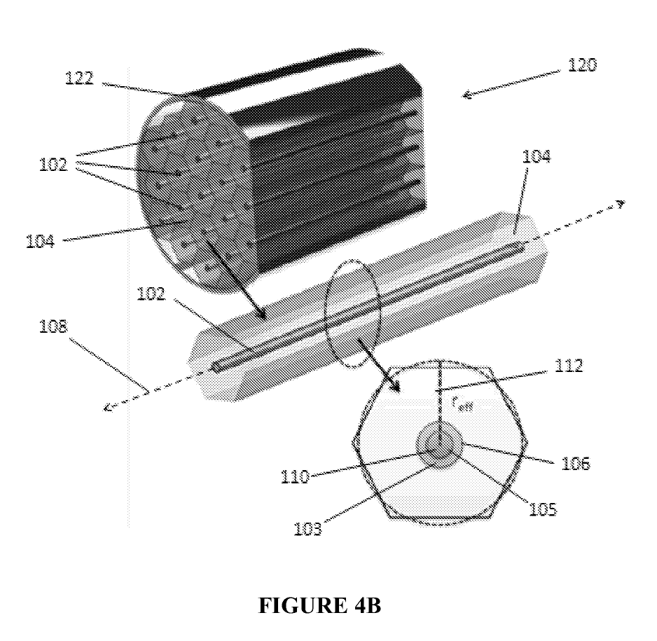

The thermal storage units can include a shell and tube-type heat exchanger. Referring now to FIG. 4A, the thermal storage unit (100) can comprise a heat exchange path (102) through which a heat exchange medium flows, and a thermal storage medium (104) in thermal contact with the heat exchange path (102). Heat exchange path (102) can comprise, for example, a tube having a central axis (108) and a tube wall (103) having an inner surface (105) and an outer surface (106). The tube wall (103) is coaxially disposed about the central axis (108) so as to define a lumen (110) through which a heat exchange medium can flow. Thermal storage unit (100) can further include a housing enclosing the heat exchange path (102) and the thermal storage medium (104).

The heat exchange path can be linear. Alternatively, the heat exchange path can be non-linear. For example, the heat exchange path can include one or more bends, curves, loops, helices, branch points, or other features, as desired. In this way, the surface area of the heat exchange path and/or the flow time of a heat exchange medium though the thermal storage unit can be varied so as to provide a thermal storage unit having the desired characteristics for heat transfer between a heat exchange medium flowing through the heat exchange path and the thermal storage medium. The heat exchange path can be substantially round when viewed in cross-section. Alternatively, the heat exchange path, when viewed in cross-section, can be square or rectangular, triangular, polygonal, oval-shaped, or any other shape or combination of shapes.

In some embodiments, the heat exchange path can be, for example a tube or conduit which provides a fluid flow path through which a heat exchange medium flows. The heat exchange path can be, for example, a tube fabricated from a thermally conductive material which is compatible with the heat exchange medium and the thermal storage medium (e.g., a material that does not substantially degrade when placed in contact with the heat exchange medium or the thermal storage medium). For example, the heat exchange path can be fabricated from metals (e.g., aluminum, aluminum alloys (e.g., marine-grade aluminum alloy), high alloy stainless steels, carbon steels, titanium, copper, or bronze) and non-metal materials (e.g., thermally-enhanced polymers or thermoset plastics). In certain embodiments, heat exchange path comprises a tube fabricated from a material, such as a metal, that permits extrusion or other seamless formation of the tube. By eliminating seams from the tube, corrosion and/or potential for leaks can be minimized.

A heat exchange medium can be flowed through the heat exchange path. The heat exchange medium can be a fluid (e.g., a liquid) which can transfer thermal energy to or from the thermal storage medium. For example, the heat exchange medium can be water, or an antifreeze/water mixture (e.g., an engine coolant). Examples of suitable antifreeze/water mixtures include aqueous solutions of ethylene glycol, propylene glycol, and/or glycerol.

Referring again to FIG. 4A, the thermal storage medium (104) can be disposed about the heat exchange path (102) in any suitable fashion, so as to ensure efficient heat transfer between a heat exchange medium flowing through the heat exchange path (102) and the thermal storage medium (104). For example, the thermal storage medium (104) can be in direct physical contact with all or a portion of the outer surface of the tube (106). In some embodiments, the thermal storage medium (104) surrounds the heat exchange path (102) (e.g., the tube), meaning that at a given point along the heat exchange path (102), the thermal storage medium (104) is coaxially disposed the heat exchange path (102) so as to form a substantially continuous layer of thermal storage medium (104) in contact with the outer surface of the tube (106).

The thermal storage unit can comprise a single heat exchange path. Alternatively, the thermal storage unit can comprise plurality of heat exchange paths through which a heat exchange medium flows. Referring now to FIG. 4B, the thermal storage unit (120) can comprise a plurality heat exchange paths (102) through which a heat exchange medium flows, and a thermal storage medium (104) in thermal contact with the plurality of heat exchange paths (102). Each of the plurality of heat exchange paths (102) can comprise, for example, a tube having a central axis (108) and a tube wall (103) having an inner surface (105) and an outer surface (106). The tube wall (103) is coaxially disposed about the central axis (108) so as to define a lumen (110) through which a heat exchange medium can flow. The central axes (108) of each of the tubes can be substantially parallel to each other, such that the thermal storage unit (120) comprises a bundle of parallel heat exchange paths (102) in thermal contact with (e.g., surrounded by) a thermal storage medium (104). The plurality of heat exchange paths (102) can be fluidly independent (i.e., not fluidly connected). Alternatively, the plurality of heat exchange paths (102) can be fluidly connected upstream and/or downstream of thermal storage unit (120). The thermal storage unit (120) can further include a housing (122) enclosing the heat exchange path (102) and the thermal storage medium (104).

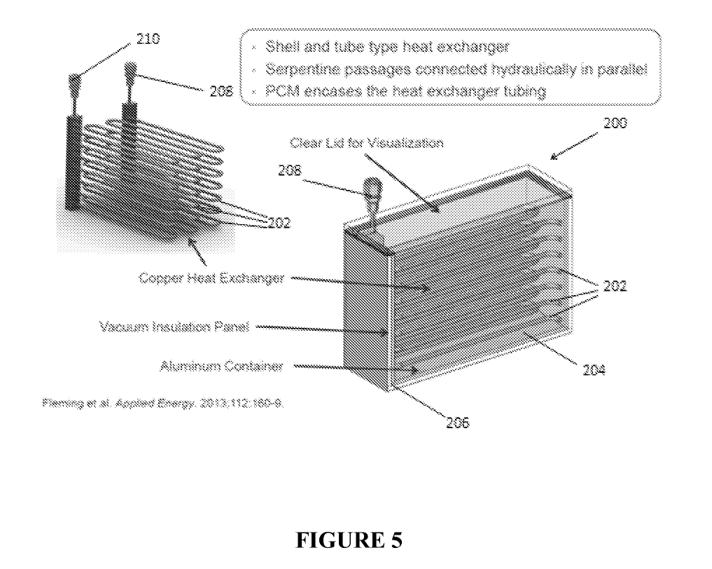

Referring now to FIG. 5, the thermal storage unit (200) can comprise a plurality of non-linear heat exchange paths (202) through which a heat exchange medium flows, and a thermal storage medium (204) in thermal contact with the plurality of heat exchange paths (202). Each of the plurality of heat exchange paths (202) can comprise, as discussed above, a tube having a central axis and a tube wall having an inner surface and an outer surface. The tube wall is coaxially disposed about the central axis so as to define a lumen through which a heat exchange medium can flow. The thermal storage medium (204) can be disposed about the plurality of heat exchange paths (202) in any suitable fashion (e.g., surrounding the plurality of heat exchange paths), so as to ensure efficient heat transfer between a heat exchange medium flowing through the plurality of heat exchange paths (202) and the thermal storage medium (204). The plurality of heat exchange paths (202) can be fluidly independent (i.e., not fluidly connected). Alternatively, the plurality of heat exchange paths (202) can be fluidly connected upstream and/or downstream of thermal storage unit (200).

The plurality of heat exchange paths (202) can be non-linear. For example, the plurality of heat exchange paths (202) can be serpentine, such that the surface area of the plurality of heat exchange paths (202) and/or the flow time of a heat exchange medium though the thermal storage unit (200) provides a thermal storage unit (200) having the desired characteristics for heat transfer between a heat exchange medium flowing through the plurality of heat exchange paths (202) and the thermal storage medium (204). The thermal storage unit (200) can further include a housing (206) enclosing the plurality of heat exchange paths (202) and the thermal storage medium (204). The housing can be fabricated from any suitable metal or non-metal, and can optionally include one or more thermal insulating layers. The thermal storage unit (200) can further comprising one or more inlet ports (208) and one or more outlet ports (210) for transferring a heat exchange medium to one or more of the heat exchange paths (202).

As described above, the thermal storage units comprise a thermal storage medium in thermal contact with the heat exchange path. The thermal storage medium can comprise a composite formed from a porous thermally conductive matrix and a PCM disposed within the porous thermally conductive matrix. By employing a composite comprising a PCM disposed within the porous thermally conductive matrix, the thermal conduction resistance of the PCM can be reduced. For example, the composite thermal storage medium can have a thermal conductivity of at least about 2 W·m⁻¹·K⁻¹ (e.g., at least about 2.5 W·m⁻¹·K⁻¹, at least about 3 W·m⁻¹·K⁻¹, at least about 3.5 W·m⁻¹·K⁻¹, at least about 4 W·m⁻¹·K⁻¹, at least about 4.5 W·m⁻¹·K⁻¹, at least about 5 W·m⁻¹·K⁻¹, at least about 5.5 W·m⁻¹·K⁻¹, at least about 6 W·m⁻¹·K⁻¹, at least about 6.5 W·m⁻¹·K⁻¹, at least about 7 W·m⁻¹·K⁻¹, at least about 7.5 W·m⁻¹·K⁻¹, at least about 8 W·m⁻¹·K⁻¹, at least about 8.5 W·m⁻¹·K⁻¹, at least about 9 W·m⁻¹·K⁻¹, at least about 9.5 W·m⁻¹·K⁻¹, at least about 10 W·m⁻¹·K⁻¹, at least about 15 W·m⁻¹·K⁻¹, or at least about 20 W·m⁻¹·K⁻¹).

The thermally conductive matrix can comprise an isotropic thermally conductive matrix. Isotropic thermally conductive matrixes are thermally conductive matrixes which exhibit substantially equivalent thermal conductivity in all orientations (e.g., along any axis within the matrix). In other embodiments, the thermally conductive matrix can comprise an anisotropic thermally conductive matrix Anisotropic thermally conductive matrixes are thermally conductive matrixes which exhibit different thermal conductivities in different orientations (e.g., different thermal conductivities along different axes within the matrix). Anisotropic thermally conductive matrixes can also be said to comprise anisotropic porosity within the matrix. Examples of anisotropic thermally conductive matrixes include the 3D-printed graphite matrixes described in more detail below.

In embodiments where the thermal storage medium comprises an anisotropic thermally conductive matrix, the thermal storage medium can comprise a thermally conductive matrix configured to exhibit an increased thermal conductivity along an axis orthogonal to heat exchange path relative to the thermal conductivity along an axis parallel to heat exchange path. For example, referring again to FIG. 4A, in some embodiments where the thermal storage medium (104) comprises an anisotropic thermally conductive matrix, the thermal storage medium (104) can comprise a thermally conductive matrix configured to exhibit an increased thermal conductivity along one or more axes (112) radially extending from the heat exchange path (102) relative to the thermal conductivity along an axis parallel to heat exchange path (e.g., an axis passing through the thermal storage medium parallel to the central axis (108) of the tube). In this way, the thermal storage medium can be configured to efficiently conduct thermal energy between the heat exchange path and the thermal storage medium.

The porous thermally conductive matrix can comprise a thermally conductive solid having a high porosity. For example, the porous thermally conductive matrix can comprise a thermally conductive solid a volume porosity of at least about 75% (e.g., at least about 80%, at least about 85%, at least about 90%, at least about 91%, at least about 92%, at least about 93%, at least about 94%, at least about 95%, at least about 96%, at least about 97%, at least about 98%, or at least about 99%). In certain embodiments, the thermally conductive matrix can comprise a thermally conductive foam. The foam can comprise closed cells, open cells, a coarse porous reticulated structure, and/or combinations thereof. In certain embodiments, the foam comprises an open-cell foam or a reticulated foam, so as to allow a PCM to be dispersed throughout the foam.

In certain embodiments, the thermally conductive matrix can comprise a metal foam. Metallic foams, including open-celled metal foams and reticulated metal foams, are known in the art, and can be produced using a variety of liquid and solid state processing methods. Suitable methods for forming metal foams can be selected in view of a number of factors, including the composition of the metal foam and the desired foam morphology (e.g., the desired volume porosity). Non-limiting examples of metals can may be included in metal foams include aluminum (Al), titanium (Ti), iron (Fe), nickel (Ni), copper (Cu), vanadium (V), cobalt (Co), zinc (Zn), cadmium (Cd), tin (Sn), tungsten (W), chromium (Cr), niobium (Nb), and molybdenum (Mo). The metal foam can comprise substantially only a single metal. Alternatively, the metal foam can comprise a combination of two or more metals. Examples of suitable metal foams include, but are not limited to, nickel foams, aluminum foams, titanium foams, bronze foams, and copper foams. In certain cases, the metal foam comprises a reticulated metal foam. Methods of making reticulated metal foams are known in the art. See, for example, U.S. Pat. No. 6,857,461 to Girlich which is incorporated herein by reference. The thermally conductive matrix can also comprise a carbon- or graphite-containing metal foam, such as a carbon- or graphite-containing nickel foam, aluminum foam, titanium foam, bronze foam, or copper foam.

In certain embodiments, the thermally conductive matrix can comprise a graphite foam, a carbon foam, or combinations thereof. Carbon and graphite foams can comprise three dimensional interconnected carbonaceous structures that exhibit high thermal conductivity. Carbon and graphite foams can be configured in a wide range of geometries based on application needs and/or heat transfer requirements. In particular, carbon and graphite foams can be configured to exhibit a high thermal conductivity, a low density, or combinations thereof. In certain embodiments, the carbon and graphite foam can be an open cell or reticulated carbon and graphite foam having a small cell or pore size. Graphite foams can also serve as anisotropic thermally conductive matrixes. Carbon and graphite foams are known in the art, and can be prepared using a variety of methodologies. See, for example, Pettes et al., Nano Lett, 12:2959-2964, 2012, and Ji et al., Nano Lett, 12:2446-2451, 2012, which are each incorporated by reference herein in their entireties for their teachings of carbon and graphite foams, and methods of making and using thereof.

For example, graphite foams can be synthesized by chemical vapor deposition (CVD) of a suitable carbon precursor on an open-celled reticulated nickel foam. After the graphite has been formed on the nickel foam, the nickel can be removed, for example using a wet etchant, to afford a graphite foam. Other suitable carbon and graphite foams include pitch-based carbon and graphite foams. See, for example, U.S. Pat. Nos. 6,033,506, 6,037,032, 6,399,149, 6,780,505, 7,014,151, 7,157,019, 7,166,237, 6,261,485, 6,387,343, 6,656,443, and 6,663,842 to Klett, all of which are incorporated herein by reference in their entirety. Suitable carbon and graphite foams, such as reticulated vitreous carbon (RVC) foams, can also be obtained from commercial sources. For example, suitable foams are commercially available under the trade name POCOFOAM® (by Poco Graphite, Inc., Decatur, Tex.).

In certain embodiments, the thermally conductive matrix can comprise a 3D-printed graphite matrix. 3D-printed graphitic matrixes are graphitic materials formed using a 3D printed template. 3D-printing can provide precise control over the morphology of the graphitic material. Accordingly, 3D-printed graphitic matrixes can possess a structure comprising a microporous network formed of continuous graphitic material.

The 3D-printed graphite matrix can be formed so as to possess any suitable morphology. Methods for preparing 3D-printed graphite matrixes can comprise forming a microporous template using a 3D-printing processes, and graphitizing the microporous template to yield a 3D-printed graphitic matrix. The microporous template can be formed from any suitable graphitizable material which can be printed using standard 3-D printing methods. For example, the microporous template can be a metal template (e.g., a nickel template) or a graphitizable polymer template. Metal (e.g., Ni) templates can be formed via Direct Metal Laser Sintering (DMLS) of metal (e.g., Ni) powders. DMLS uses a small diameter laser to sinter metal powders to form a metallurgic bond. The laser path is controllable and by continually adding more layers of metal powder, a microporous metal template can be printed based on a digital model. A variety of 3D-printing processes, including stereolithography and selective laser sintering, can be used to form microporous polymer templates. The structure of the template can be individually designed for a specific application, i.e., rationally designed. For example, the 3D graphitic matrix can be designed to have a structure that corresponds to a desired path for thermal transmission.

Once formed using 3-D printing methods, the microporous template can be graphitized. Methods for graphitizing the matrix can vary depending upon a number of factors, including the composition of the microporous template. Metal templates (e.g., Ni templates) can be graphitized using high temperature chemical vapor deposition (CVD) to form a graphite matrix on the surface of the metal template. Once the graphite matrix has been formed, the metal template can be etched away, as described above. Templates formed from a graphitizable polymer can graphitized through pyrolysis of the graphitizable polymer. This process can form a 3D-graphitic matrix directly from the microporous template. Polymer templates can also be graphitized by metalizing the polymer template, and then graphitizing the metalized polymer template using the methods described above for graphitizing metal templates.

In some embodiments, the 3D-printed graphite matrix can be formed to facilitate incorporation of the 3D-printed graphite matrix in a thermal storage unit. By way of example, the 3D-printed graphite matrix can be fabricated as shown in FIG. 1, and described herein more fully above. Although a specific radial and circumferential designed pattern is illustrated in FIG. 1, other similarly tailored microporous structures can be produced. The 3D-printed graphite matrix can serve as the thermal storage medium of the thermal storage units described above, wherein the cylindrical opening (514) accommodates, for example, a tube or pipe which serves as a heat exchange path.

In some embodiments, the cylindrical opening (514) can have a radius ranging from greater than about 0 mm to about 15 mm (e.g. 0-1 mm, 1-2 mm, 2-3 mm, 3-4 mm, 4-5 mm, 5-7 mm, 7-9 mm, 9-11 mm, 11-13 mm, 13-15 mm, or any combinations of these ranges). In some embodiments, the cylindrical opening (514) can have a radius of from about 1.5 mm to about 6.5 mm (e.g. 1.5-2 mm, 2-2.5 mm, 2.5-3 mm, 3-3.5 mm, 3.5-4 mm, 4-4.5 mm, 4.5-5 mm, 5-5.5 mm, 5.5-6 mm, 6-6.5 mm, or any combinations of these ranges). The circumferential thin walls (506) and the radius thin walls (504) can have a thickness of from about 0.01 μm to about 1 μm (e.g. 0.01-0.05 μm, 0.05-0.1 μm, 0.1-0.15 μm, 0.15-0.2 μm, 0.2-0.25 μm, 0.25-0.3 μm, 0.3-0.35 μm, 0.35-0.4 μm, 0.4-0.45 μm, 0.45-0.5 μm, 0.5-0.55 μm, 0.55-0.6 μm, 0.6-0.65 μm, 0.65-0.7 μm, 0.7-0.75 μm, 0.75-0.8 μm, 0.8-0.85 μm, 0.85-0.9 μm, 0.9-0.95 μm, 0.95-1 μm, or any combinations of these ranges). In some embodiments, the pores (508) can have an average pore size, measured as the largest cross-sectional dimension of the pores, of from 100 μm to 5000 μm (e.g. 100-200 μm, 200-300 μm, 300-400 μm, 400-500 μm, 500-750 μm, 750-1000 μm, 1000-1250 μm, 1250-1500 μm, 1500-1750 μm, 1750-2000 μm, 2000-2500 μm, 2500-3000 μm, 3000-3500 μm, 3500-4000 μm, 4000-4500 μm, 4500-5000 μm, or any combinations of these ranges). The height of the 3D-printed graphite matrix can be from 0.2 mm to 100 mm (e.g. 0.2-1 mm, 1-5 mm, 5-10 mm, 10-20 mm, 20-30 mm, 30-40 mm, 40-50 mm, 50-75 mm, 75-1000 mm, or any combinations of these ranges). The 3D-printed graphite matrix can have a width, a length, or a diameter from 5 mm to 500 mm (e.g. 5-10 mm, 10-20 mm, 20-40 mm, 40-60 mm, 60-100 mm, 100-150 mm, 150-200 mm, 200-250 mm, 250-300 mm, 300-350 mm, 350-400 mm, 400-450 mm, 450-500 mm or any combinations of these ranges).

The thermally conductive matrix (e.g., the graphite foam, the carbon foam, the 3D-printed graphite matrix, the metal foam, or combinations thereof) can be modified using carbon nanomaterials. In some embodiments, the thermally conductive matrix (e.g., the graphite foam, the carbon foam, the 3D-printed graphite matrix, the metal foam, or combinations thereof) can further comprise a layer of carbon nanotubes disposed on the thermally conductive matrix (e.g., a layer of carbon nanotubes disposed on the graphite foam, the carbon foam, the 3D-printed graphite matrix, the metal foam, or combinations thereof).

For example, a layer of carbon nanotubes can be disposed on a carbon substrate (e.g., a graphite foam, a carbon foam, a 3D-printed graphite matrix, or combinations thereof). The carbon nanotubes can be formed the carbon substrate by any of the processes described herein more fully above.

In some embodiments, the layer of carbon nanotubes disposed on the thermally conductive matrix (e.g., a layer of carbon nanotubes disposed on the graphite foam, the carbon foam, the 3D-printed graphite matrix, the metal foam, or combinations thereof) can comprise carbon nanotubes form a plurality of carbon nanotubes from about 1 to about 500 μm in length. The carbon nanotubes on the carbon substrate can be from about 1 to about 50 nm in diameter (e.g., about 1 nm, about 5 nm, about 10 nm, about 15 nm, about 20 nm, about 25 nm, about 30 nm, about 35 nm, about 40 nm, about 45 nm, or about 50 nm in diameter). In a certain examples, the carbon nanotubes are about 10 nm in diameter. In some examples, the carbon nanotubes can comprise single walled nanotubes, double walled nanotubes, multi-walled nanotubes, or a combination thereof.

In certain embodiments, the thermally conductive matrix (e.g., the graphite foam, the carbon foam, the 3D-printed graphite matrix, the metal foam, or combinations thereof) can comprise a conformal layer of carbon nanotubes disposed on the thermally conductive matrix (e.g., the graphite foam, the carbon foam, the 3D-printed graphite matrix, the metal foam, or combinations thereof). In these embodiments, the carbon nanotubes can be disposed in a substantially even layer on all surfaces of the thermally conductive matrix.

In some embodiments, the surface of the thermally conductive matrix (e.g., the graphite foam, the carbon foam, the 3D-printed graphite matrix, the metal foam, or combinations thereof) can be modified to improve compatibility between the thermally conductive matrix and a PCM to be disposed within the porous thermally conductive matrix. For example, in some embodiments, the thermally conductive matrix (e.g., the graphite foam, the carbon foam, the 3D-printed graphite matrix, the metal foam, or combinations thereof) can be modified to increase its hydrophobicity to improve compatibility between the thermally conductive matrix and a PCM to be disposed within the porous thermally conductive matrix. For example, the thermally conductive matrix (e.g., the graphite foam, the carbon foam, the 3D-printed graphite matrix, the metal foam, or combinations thereof) can be subjected to plasma treatment prior to incorporation of a PCM within the matrix. Plasma treatment can remove impurities and contaminants from the matrix surface and/or modify the hydrophobicity of the surface (i.e., increase the hydrophilicity of the matrix surface).

As discussed above, the thermal storage medium can comprise a PCM disposed within the thermally conductive matrix. A phase change material is a substance with a high heat of fusion which, melting and solidifying at a certain temperature, is capable of storing and releasing large amounts of energy. Heat is absorbed or released when the material changes from solid to liquid and vice versa. The PCM can be disposed within the thermally conductive matrix using any suitable method. For example, the PCM can be disposed within the thermally conductive matrix by contacting the PCM and the thermally conductive matrix, for example, by soaking, dipping, spraying, pouring, immersing, or combinations thereof.

Any suitable PCM can be disposed within the thermally conductive matrix. For example, the PCM can comprise water, a salt-water solution, a sugar alcohol, a paraffin, a fatty acid, a salt hydrate, a nitrate, a hydroxide, a hygroscopic material, or combinations thereof. More specifically, the phase change material may be erythritol; xylitol; mannitol; galactitol; a blend of galactitol and mannitol; urea; ureidopyrimidone; N,N-dialkylpiperidinum; N,N-dialkylpyrrolidinium; LiF and BeF₂; NaF and BeF₂; LiF and NaF and KF; NaF and ZrF₄; KNO₃ and KCl; KNO₃ and K₂CO₃; LiBr and KBr; KNO₃ and KBr; KNO₃ and LiOH; FeCl₂ and KCl; KCl and LiCl; K₂CO₃ and KOH; K₂SO₄ and KOH; FeCl₂ and NaCl; KCl and MnCl₂; LiBr and LiI; KCl—MgCl₂; MnCl₂ and NaCl; LiCO₃ and LiOH; LiBr and LiF; NaCl and MgCl₂; K₂CO₃ and MgCO₃; KF and KBF₄; Na₂SO₄ and ZnSO₄; CaCl₂ and LiCl; LiCl and Li₂SO₄; KF and LiF; K₂CO₃ and Li₂CO₃; Li₂CO₃ and Na₂CO₃; LiCl and LiF; CaCl₂ and NaCl; KVO₃ and BaTiO₃; KCl and LiBr and NaBr; KBr and LiCl and NaCl; LiBr and NaBr and KBr; NaOH and NaCl and Na₂CO₃; KCl and LiCl and Li₂SO₄; MgCl₂ and KCl and NaCl; NaCl and KCl and FeCl₂; KCl and LiCl and CaF₂; CaCl₂ and KCl and LiCl; NaCl and KCl and LiCl; KF and AlF₃ and ZrF₄; MnCl₂ and KCl and NaCl; Na₂SO₄ and K₂SO₄ and ZnSO₄; Na₂CO₃ and K₂CO₃ and ZnSO₄; Na₂CO₃ and K₂CO₃ and LiCO₃; KCl and NaCl and LiF; LiCl and NaCl and Li₂SO₄; LiCl and KCl and CaCl₂ and CaF₂; KCl and NaCl and LiCl and Li₂SO₄; NaNO₃; KNO₃; KNO₃ and KCl; KNO₃ and K₂CO₃; KNO₃ and KBr; FeCl₂ and KCl; KCl and LiCl; K₂CO₃ and KOH; K₂SO₄ and KOH; FeCl₂ and NaCl; LiBr and KBr; NaOH and NaCl and Na₂CO₃; MgCl₂ and KCl and NaCl; NaCl and KCl and FeCl₂; CaCl₂ and KCl and LiCl; MgCl₂ and KCl and NaCl; MgCl₂ and KCl and NaCl; NaOH and NaCl and Na₂CO₃; MnCl₂ and KCl and NaCl; Na₂CO₂ and K₂CO₃ and Li₂CO_{3;} LiF and LiCl and LiVO₃ and Li₂SO₄ and Li₂MoO₄; LiF and LiCl and Li₂SO₄ and Li₂MoO₄; LiF and KF and KCO₄ and KCl; LiF and LiOH; LiF and BaF₂ and KF and NaF; LiF and KF and NaF and KCl; LiF and NaF and KF and MgF₂; LiF and NaF and KF; LiF and KF and NaF; LiF and NaF and KF; LiF and LiCl; KF and LiCl; KF and LiCl; LiF and KF; LiF and LiVO₃ and Li₂MoO₄; LiCl and KCl and LiCO₃ and LiF; LiCl and KCl; KCl and MnCl₂ and NaCl; LiClLiVO₃ and Li₂MoO₄ and Li₂SO₄ and LiF; NaCl and KCl and MgCl₂; KCl and MgCl₂ and NaCl; NaCl and MgCl₂; KCl and ZnCl₂; KCl and MgCl₂; NaCl═MgCl₂; LiCl and Li₂SO₄ and Li₂MoO₄; KCl and MnCl₂; LiCl and Li₂SO₄ and LiVO₃; KCl and MnCl₂; NaCl and MgCl₂; CaCl₂ and KCl and NaCl and NaF; CaCl₂ and KCl and MgCl₂ and NaCl; CaCl₂ and KCl and NaCl; KCl and MgCl₂; LiCl and LiF and MgF₂; CaCl₂ and CaF₂ and NaF; CaCl₂ and NaCl; NaOH and NaCl and Na₂CO₃; LiOH and LiF; Li₂CO₃ and K₂CO₃ and Na₂CO₃; Li₂CO₃ and K₂CO₃; Li₂CO₃ and K₂CO₃; Zn and Mg; Al and Mg and Zn; Mg and Cu and Zn; Mg and Cu and Ca; Mg and Al; formic acid; caprilic acid; glycerin; D-Lactic acid; methyl palmitate;

camphenilone; docasyl bromide; caprylone; phenol; heptadecanone; 1-cyclohexylooctadecane; 4-heptadacanone; p-joluidine; cyanamide; methyl eicosanate; 3-heptadecanone; 2-heptadecanone; hydrocinnamic acid; cetyl alcohol; α-nepthylamine; camphene; O-nitroaniline; 9-heptadecanone; thymol; sodium acetate; trimethylolethane; methylbehenate; diphenyl amine; p-dichlorobenzene; oxalate; hypophosphoric acid; O-xylene dichloride; β-chloroacetic acid; nitro naphthalene; trimyristin; heptaudecanoic acid; α-chloroacetic acid; bee wax; bees wax; glycolic acid; glyolic acid; p-bromophenol; azobenzene; acrylic acid; dinto toluent; phenylacetic acid; thiosinamine; bromcamphor; durene; benzylamine; methyl bromobenzoate; alpha napthol; glautaric acid; p-xylene dichloride; catechol; quinine; acetanilide; succinic anhydride; benzoic acid; stibene; benzamide; acetic acid; polyethylene glycol; capric acid; eladic acid; lauric acid; pentadecanoic acid; trustearin; myristic acid; palmatic acid; stearic acid; acetamide; methyl fumarate; K₂HPO₄.6H₂O; FeBr₃.6H₂O; Mn(NO₃)₂.6H₂O; FeBr₃.6H₂O; CaCl₂.12H₂O; LiNO₃.2H₂O; LiNO₃.3H₂O; Na₂CO₃.10H₂O; Na₂SO₄.10H₂O; KFe(SO₄)₂.12H₂O; CaBr₂.6H₂O; LiBr₂.2H₂O; Zn(NO₃)₂.6H₂O; FeCl₃.6H₂O; Mn(NO₃)₂.4H₂O; Na₂HPO₄.12H₂O; CoSO₄.7H₂O; KF.2H₂O; MgI₂.8H₂O; CaI₂.6H₂O; K₂HPO₄.7H₂O; Zn(NO₃)₂.4H₂O; Mg(NO₃).4H₂O; Ca(NO₃).4H₂O; Fe(NO₃)₃.9H₂O; Na₂SiO₃.4H₂O; K₂HPO₄.3H₂O; Na₂S₂O₃.5H₂O; MgSO₄.7H₂O; Ca(NO₃)₂.3H₂O; Zn(NO₃)₂.2H₂O; FeCl₃.2H₂O; Ni(NO₃)₂.6H₂O; MnCl₂.4H₂O; MgCl₂.4H₂O; CH₃COONa.3H₂O; Fe(NO₃)₂.6H₂O; NaAl(SO₄)₂.10H₂O; NaOH.H₂O; Na₃PO₄.12H₂O; LiCH₃COO.2H₂O; Al(NO₃)₂.9H₂O; Ba(OH)₂.8H₂O; Mg(NO₃)₂.6H₂O; KAl(SO₄)₂.12H₂O; MgCl₂.6H₂O; gallium-gallium antimony eutectic; gallium; cerrolow eutectic; Bi—Cd—In eutectic; cerrobend eutectic; Bi—Pb—In eutectic; Bi—In eutectic; Bi—Pb-tin eutectic; Bi—Pb eutectic; CaCl₂.6H2O and CaBr₂.6H₂O; Triethylolethane and water and urea; C₁₄H₂₈O₂ and C₁₀H₂₀O₂; CaCl₂ and MgCl₂.6H₂O; CH₃CONH₂ and NH₂CONH₂; Triethylolethane and urea; Ca(NO₃).4H₂O and Mg(NO₃)₃.6H₂O; CH₃COONa.3H₂O and NH₂CONH₂; NH₂CONH₂ and NH₄NO₃; Mg(NO₃)3.6H₂O and NH₄NO₃; Mg(NO₃)₃.6H₂O and MgCl₂.6H₂O; Mg(NO3)3.6H₂O and MgCl₂.6H₂O; Mg(NO3)3.6H₂O and Al(NO₃)₂.9H₂O; CH₃CONH₂ and C₁₇H₃₅COOH; Mg(NO₃)₂.6H₂O and MgBr₂.6H₂O; Napthalene and benzoic acid; NH₂CONH₂ and NH₄Br; LiNO₃ and NH₄NO₃ and NaNO₃; LiNO₃ and NH₄NO₃ and KNO₃; LiNO₃ and NH₄NO₃ and NH₄Cl; or combinations thereof.

In some embodiments, the melting temperature of the PCM can be at least about −100° C. (e.g., at least about −50° C., at least about 0° C., at least about 50° C., at least about 100° C., at least about 150° C., at least about 200° C., at least about 250° C., at least about 300° C., at least about 350° C. or at least about 400° C.). In some embodiments, the melting temperature of the PCM can be about 400° C. or less (e.g., about 350° C. or less, about 300° C. or less, about 250° C. or less, about 200° C. or less, about 150° C. or less, about 100° C. or less, about 50° C. or less, about 0° C. or less, or about −50° C. or less). The melting temperature of the PCM can range from any of the minimum temperatures described above to any of the maximum temperatures described above. For example, the melting temperature of the PCM can range from about −100° C. to about 400° C. (e.g., from about 0° C. to about 300° C., or from about 100° C. to about 200° C.).

In certain embodiments, the PCM comprises a salt water solution, and has a melting temperature of from about −100° C. to about 0° C. In some embodiments, the PCM comprises a paraffin, and has a melting temperature of from about 0° C. to about 150° C. In some embodiments, the phase change material is a salt hydrate with a melting temperature of 50° C. to 100° C. In some embodiments, the phase change material comprises a sugar alcohol, and has a melting temperature of from about 50° C. to about 225° C. In some embodiments, the phase change material comprises a nitrate, and has a melting temperature of from about 150° C. to about 300° C. In some embodiments, the phase change material comprises a hydroxide, and has a melting temperature of from about 200° C. to about 400° C.

In some embodiments, the melting enthalpy of the PCM can be at least about 100 MJ/m³ (e.g., at least about 150 MJ/m³, at least about 200 MJ/m³, at least about 250 MJ/m³, at least about 300 MJ/m³, at least about 350 MJ/m³, at least about 400 MJ/m³, at least about 450 MJ/m³, at least about 500 MJ/m³, at least about 550 MJ/m³, at least about 600 MJ/m³, or at least about 650 MJ/m³). In some embodiments, the melting enthalpy of the PCM can be about 100 MJ/m³ or less (e.g., about 650 MJ/m³ or less, about 600 MJ/m³ or less, about 550 MJ/m³ or less, about 500 MJ/m³ or less, about 450 MJ/m³ or less, about 400 MJ/m³ or less, about 350 MJ/m³ or less, about 300 MJ/m³ or less, about 250 MJ/m³ or less, about 200 MJ/m³ or less, or about 150 MJ/m³ or less). The melting enthalpy of the PCM can range from any of the minimum values described above to any of the maximum values described above. For example, the melting enthalpy of the PCM can range from about 100 MJ/m³ to about 100 MJ/m³ (e.g., from about 200-400 MJ/m³).

In some embodiments, the phase change material comprises a salt water solution, and has a melting enthalpy of from about 150 MJ/m³ to about 300 MJ/m³. In some embodiments, the phase change material comprises a paraffin, and has a melting enthalpy of from about 150 MJ/m³ to about 200 MJ/m³. In some embodiments, the phase change material comprises a salt hydrate, and has a melting enthalpy of from about 200 MJ/m³ to about 600 MJ/m³. In some embodiments, the phase change material comprises a sugar alcohol, and has a melting enthalpy of from about 200 MJ/m³ to about 400 MJ/m³. In some embodiments, the phase change material comprises a nitrate, and has a melting enthalpy of from about 200 MJ/m³ to about 600 MJ/m³. In some embodiments, the phase change material comprises a hydroxide, and has a melting enthalpy of from about 450 MJ/m³ to about 700 MJ/m³.

In some embodiments, the phase change material comprises a sugar alcohol or a blend of sugar alcohols. In certain embodiments, the PCM comprises a blend of mannitol and galactitol, as described herein more fully above.

Galactitol and mannitol can be present in the galactitol and mannitol blend in a weight ratio of from about 9:1 to about 1:9.

The galactitol and mannitol blend can be the major component of the PCM. For example, the amount of the galactitol and mannitol blend can be at least about 75 wt. % of the total PCM. In other examples, the amount of galactitol and mannitol blend can be at least about 75, about 80, about 85, about 90, about 95, about 98, or about 99 wt. % of the total PCM, where any of the stated values can form an upper or lower endpoint of a range.

In certain embodiments, the thermal storage medium can comprise a PCM disposed within the thermally conductive matrix, wherein the PCM comprises a blend of galactitol and mannitol in a weight ratio of about 1:1 which has a melting point of about 151 to about 153° C. and a latent heat of fusion of from about 300 J/g to about 310 J/g.

The PCM disposed within the thermally conductive matrix can optionally comprise one or more additives. Examples of suitable additives include viscosity modifiers, antimicrobial agents, fire retardants, agents to prevent supercooling, thickeners, antioxidants, corrosion inhibitors and combinations thereof.

The thermal storage units described herein can be used in any application where the storage of thermal energy is desirable. For example, the thermal storage units can be used to collect thermal energy for later use (e.g., hours, days or many months later). In this way, the thermal storage units can be used to improve energy efficiency in a wide variety of applications. For example, the thermal storage units described herein can be utilized in conjunction with heating and/or cooling systems (e.g., in conjunction with HVAC systems in vehicles such as cars and airplanes as well as in buildings), in conjunction with solar energy collection and utilization, in conjunction with refrigeration, or in conjunction with industrial processes. The thermal storage units described herein can be tailored for use in particular applications (e.g., for operation in various ranges of powers/energies) by adjusting the materials incorporated in the thermal storage unit to provide a thermal storage unit configured to operate in conjunction with different temperature regimes (e.g. by choosing a suitable PCM).

By way of example, the thermal storage units described herein can be incorporated into HVAC systems in vehicles, such as electric vehicles (EVs). Thermal storage units can be use to provide a low cost heating and cooling system to provide climate conditioning to an EV's cabin through stored thermal energy rather than energy from the Li-ion battery. In this way the driving range and efficiency of EVs can be improved. An example system for use in EVs can include two thermal storage units, referred to as the hot thermal battery and the cold thermal battery, each containing a different PCM. A heat transfer fluid (HTF) can be circulated between a cabin air heat exchanger and either thermal battery depending on operation mode (e.g., heating or cooling of the cabin air). Heating can be achieved through solidification of a high temperature PCM present in the hot thermal battery and cooling can be achieved through melting of a low temperature PCM in the cold thermal battery. The thermal batteries can be recharged by circulating the HTF through an off-board charge station configured to provide or extract the heat needed for reversing the phase change process within the batteries while the EV's Li-ion battery is charging. The charge station can be configured such that the charge time for recharging the thermal batteries is less than the charge time for recharging the Li-ion battery charge time.

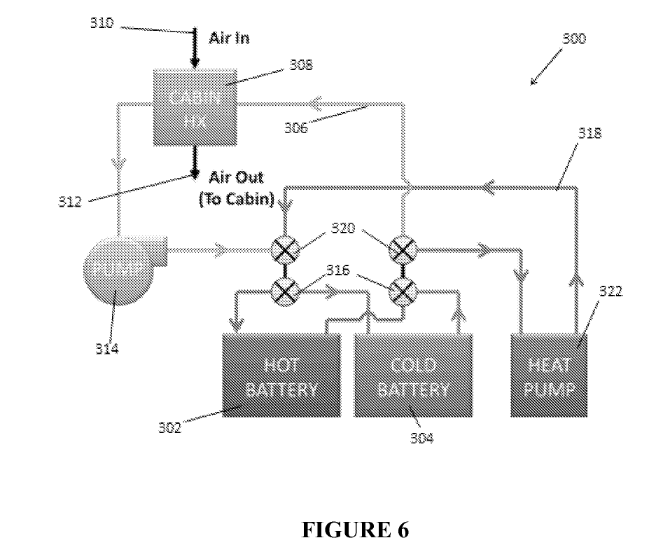

An example thermal control system for use in an EV is schematically illustrated in FIG. 6. The system (300) can include two thermal batteries, a hot thermal battery (302) and a cold thermal battery (304). The heat exchange path of each of the thermal batteries can be fluidly connected to a closed-loop heat transfer fluid flow path (306), which is fluidly connected to a liquid-air heat exchanger (LAHX, 308). The LAHX (308) can include the heat transfer fluid flow path (306) and an air flow path in thermal contact with the heat transfer fluid flow path (306). The air flow path can fluidly connect an air intake (310) and an air outlet (312). The air intake (310) can be fluidly connected to the cabin of the EV and/or the vehicle exterior. The air outlet (312) can be fluidly connected to the cabin of the EV. The LAHX (308) can be configured to exchange thermal energy between the HTF flowing through heat transfer fluid flow path (306) and air flowing through the air flow path. In this way, unconditioned air (e.g., from the cabin interior and/or from the vehicle exterior) flowing into the air intake (310) and through the LAHX (308) can be conditioned to a desired air temperature set point via heat exchange with the HTF flowing through heat transfer fluid flow path (306). Once conditioned, the air can flow from the air flow path to the cabin interior via the air outlet (312).

The system can further include a pump (314) fluidly connected to the heat transfer fluid flow path (306), and configured to induce HTF flow through the heat transfer fluid flow path (306). The system can also further include a plurality of control valves (e.g., three-way fluid flow valves, 316) configured to direct fluid flow from the heat transfer fluid flow path (306) through either the hot thermal battery (302) or the cold thermal battery (304), depending on whether the air flowing through the air flow path of LAHX (308) needs to be heated or cooled to reach the desired air temperature set point. For example, during solidification (HVAC heating mode and hot battery discharge), latent heat is released to the HTF and then dissipated to the air. During melting, the heat flow is reversed (i.e., the cabin is cooled) and the cold battery is in discharging mode.

The system can further include a recharging fluid flow loop (318) fluidly connected to the heat transfer fluid flow path (306) by a second plurality of control valves (e.g., three-way fluid flow valves, 320). The recharging fluid flow loop (318) can be fluidly connected to an offboard heat pump/heat exchanger (322). Actuation of the control valves (320) can fluidly connect either the hot thermal battery (302) or the cold thermal battery (304) to the recharging fluid flow loop (318). The batteries can then be recharged by circulating the HTF through an offboard heat pump/heat exchanger (322) and the batteries (302 and 304) to provide the requisite heating or cooling needed to recharge the battery.

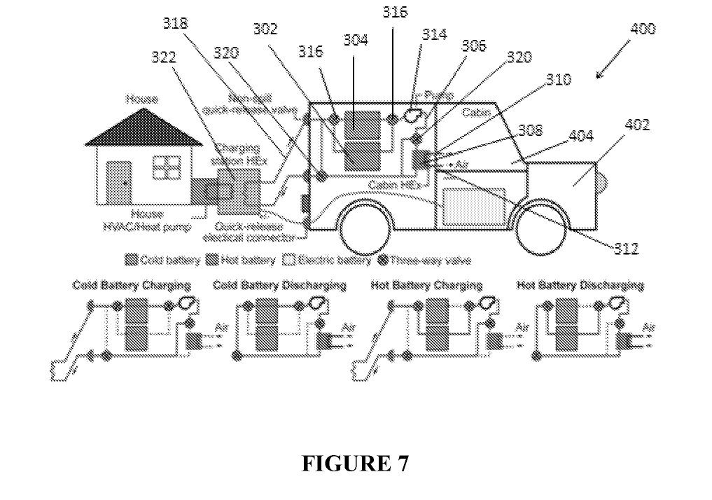

An example of a similar thermal control system (400) for use in conditioning air in the cabin (404) of an EV (402) is schematically illustrated in FIG. 7. The system (400) is similar to the system illustrated in FIG. 6; however, the positioning of certain fluidly connected elements differs.

### EXAMPLES

The following examples are set forth below to illustrate the methods and results according to the disclosed subject matter. These examples are not intended to be inclusive of all aspects of the subject matter disclosed herein, but rather to illustrate representative methods and results. These examples are not intended to exclude equivalents and variations of the present invention which are apparent to one skilled in the art.

Efforts have been made to ensure accuracy with respect to numbers (e.g., amounts, temperature, etc.) but some errors and deviations should be accounted for. Unless indicated otherwise, parts are parts by weight, temperature is in ° C. or is at ambient temperature, and pressure is at or near atmospheric. There are numerous variations and combinations of reaction conditions, e.g., component concentrations, temperatures, pressures and other reaction ranges and conditions that can be used to optimize the product purity and yield obtained from the described process. Only reasonable and routine experimentation will be required to optimize such process conditions.

### Example 1

Galactitol (or Dulcitol) (99+%, Alfa aesar) and mannitol (99%, Acros) were used as received. Distilled water was used to prepare mixtures of sugar alcohols. Differential scanning calorimetry (DSC) measurements were carried out using a METTLER TOLEDO DSC823e. Heating and cooling rates of 5° C./min were typically employed. All experiments were done under the nitrogen flow of 50 mL/min. All measurements were accurate up to 0.001 mg in an aluminum sealed cell. The DSC was calibrated for heat flow and temperature using an indium and zinc standards. All samples were preheated to 80° C., allowed to cool down to its crystallization point, and reheated for data collection. The melting point and heat of fusion were reported from the second heating cycle.

In a typical procedure, galactitol and mannitol were mixed in a 20 mL vial in a ratio to yield desired weight fraction of individual sugar alcohols in the mixture. To this mixture 10 mL of distilled water was added and the mixture was stirred at 50° C. for 10 min, then the temperature of the solution was increased to 100° C. to evaporate the water. The solid obtained was uniformly pulverized in a mortar and dried at 100° C. under vacuum for 16 h. The mixtures with different weight ratio of galactitol and mannitol were prepared by following the same procedure. Table 1 summarizes thermal properties of galactitol and mannitol blends measured using a DSC.

TABLE 1
Thermal properties of galactitol and mannitol mixtures

| galactitol | mannitol | melting point | heat of fusion |
|---|---|---|---|
| (Wt %) | (Wt %) | (° C.) | (Jg⁻¹) |
| 100 | 0 | 187 | 354 |
| 0 | 100 | 162 | 326 |
| 90 | 10 | 179 | 293 |
| 80 | 20 | 173 | 280 |
| 70 | 30 | 152 | 300 |
| 60 | 40 | 152 | 309 |
| 50 | 50 | 153 | 309 |
| 55 | 45 | 153 | 309 |
| 48 | 52 | 153 | 302 |
| 45 | 55 | 153 | 303 |

Other sugar alcohol blends were prepared using similar techniques. These are shown in Table 2.

TABLE 2
Thermal properties of sugar alcohols and their mixtures

| | Weight | Melting point | Heat of fusion |
|---|---|---|---|
| Materials | (%) | (° C.) | (Jg⁻¹) |
| Galactitol (G) | 100 | 187 | 354 |
| Erythritol (E) | 100 | 118 | 323 |
| Mannitol (M) | 100 | 162 | 326 |
| Xylitol (X) | 100 | 94 | 236 |
| GE | 1:1 | 152 | 124 |
| GX | 1:1 | 154 | 89 |
| GM | 1:1 | 152 | 305 |
| GEM | 1:1 | 125 | 39 |
| GMX | 1:1:1 | 152 | 13 |
| GEX | 1:1:1 | 150 | 10 |
| G + 10% Glycerol | 9:1 | 181 | 328 |
| G + 10% Polyethylene glycol | 9:1 | 186 | 294 |
| G + KNO₃ | 1:1 | 171 | 288 |
| GM | 9:1 | 179 | 293 |
| GM (melt mixed) | 1:1 | 153 | 252 |

### Example 2

Carbon foams were synthesized by precipitation of graphite on Ni foam and subsequent removal of the Ni with a wet etchant (Nano Lett. 12:2446-2451, 2012 and Nano Lett. 12:2959-2964, 2012, which are incorporated by reference herein in their entirety for their teaching of graphite foams and methods for their synthesis).

The graphite foam was fabricated by saturation of the Ni foam and precipitation of graphite on its surface during cool down. The Ni foam was used either as purchased, or annealed for ˜24 hours at 1100° C. under flowing H₂ (40 sccm, 99.999%) at about 50 Torr and cooled back to room temperature at 10° C. min⁻¹. The Ni foam was cut into 2 cm by 5 cm strips and loaded into a 1 inch fused quartz tube in a hot wall furnace. The Ni foam was positioned at the center of the furnace. The quartz tube was evacuated, then filled with a gas mixture of Ar (40 sccm, 99.999%) and H₂ (10 sccm, 9.999%) until the chamber reached atmospheric pressure. The furnace was heated to 1050° C. at atmospheric pressure under flowing Ar (40 sccm, 99.999%) and H₂ (10 sccm, 99.999%). The Ni foam was annealed under H₂ for 30 minutes before introducing CH₄ (99.999%). The Ni foam was exposed to 40 sccm Ar, 5 sccm CH₄ and 5 sccm H₂ for 1-3 hours at 1050° C., then cooled at a rate of 10° C. min⁻¹ to room temperature. The as-synthesized foam was cut into several long strips, each 3-5 mm wide, and the Ni was subsequently removed with a wet etchant.

The Ni of the graphite-coated nickel foam was etched in either dilute HCl (5 wt %) at 80° C. for 20 hours, in Fe(NO₃)₃ (1 M) at 80° C. for 15 days followed by HNO₃ (5 wt %) at 80° C. for about 5 days, or in (NH₄)₂S₂O₈ (1 M) at 80° C. for 15 days followed by HNO₃ (0.5 M) for 80° C. for 3 days. The graphite foam was then gently placed in several baths of deionized water, and finally rinsed in isopropanol before drying at 50° C. in ambient conditions.

A summary of synthesis conditions, mass density, and corresponding room temperature thermal properties for each graphite foam sample is given in Table 3.

TABLE 3
Synthesis conditions, mass density, and room temperature effective
and solid thermal conductivity of graphene based foam

| Sample | | Growth | | ρ_{m, GF} | κ_{GF} | κ_{G} |
|---|---|---|---|---|---|---|
| No. | Ni foam | time | Ni etchant | (10⁻³ g cm⁻³) | (W m⁻¹ K⁻¹) | (W m⁻¹ K⁻¹) |
| 1 | as-purchased | 1 | HCl | 10.0 ± 2.1 | 0.26 | 176 ± 37 |
| 2 | as-purchased | 1 | Fe(NO₃)₃ | 9.6 ± 1.8 | 0.71 | 500 ± 95 |
| 3 | annealed | 1 | Fe(NO₃)₃ | 9.9 ± 1.9 | 0.71 | 486 ± 93 |
| 4 | annealed | 1 | (NH₄)₂S₂O₈ | 11.6 ± 1.9 | 1.70 | 995 ± 162 |
| 5 | annealed | 3 | HCl | 32.0 ± 2.7 | 2.28 | 484 ± 41 |
| 6 | annealed | 3 | (NH₄)₂S₂O₈ | 31.7 ± 2.7 | 2.12 | 454 ± 38 |

### Example 3

Carbon foams were synthesized by precipitation of graphite on Ni foam and subsequent removal of the Ni with electrolytic etching.

The graphite foam was fabricated by saturation of the Ni foam and precipitation of graphite on its surface during cool down. The Ni foam was cut to fit the tube furnace at the flat temperature zone of the furnace. The piece of Ni foam was loaded into the 1 inch quartz tube of the furnace and the tube was evacuated to a pressure of <10 mTorr. A gas mixture of Ar (90 sccm, 99.9%) and H₂ (10 sccm, 99.9%) was then flowed through the tube. The furnace was ramped to 1050° C. and held at that temperature for 30 minutes with the gas mixture still flowing. The gas mixture was then changed to a mixture of argon (40 sccm, 99.9%), hydrogen (5 sccm, 99.9%) and methane (5 sccm, 99.9%). The pressure was increased to 1 atm in the tube. The temperature was maintained at 1050° C. for one hour with the gas mixture flowing. The sample was then cooled at a rate of 10° C. min⁻¹ to room temperature and unloaded.

The Ni of the graphite-coated nickel foam was electrolytically etched. An electrolyte solution was prepared with 1 M boric acid, 1 M nickel salt, and 1 mM surfactant in deionized water. The graphite-coated nickel foam was attached to the anode and a piece of nickel foil was attached to the cathode of a DC power source. Both electrodes were immersed in the electrolyte solution. A DC voltage in the range of 1-8 V was applied for 1-60 minutes. The graphite foam was rinsed with deionized water and isoproponal, then dried on a hotplate at 50° C.

### Example 4

Carbon nanotubes were grown on a graphite foam using atomic layer deposition. The graphite foam underwent oxygen-plasma treatment for 1 minute. The graphite foam was then coated with a 5 nm layer of aluminum oxide (Al₂O₃) buffer layer using atomic layer deposition. The Al₂O₃ coated graphite foam was then loaded into a quartz tube furnace, where the pressure was reduced to <10 mTorr. A gas mixture of argon (99.9%) and hydrogen (99.9%) were flowed over the sample at a flow rate of 9:1. The working pressure was then increased to atmospheric pressure and the furnace was heated to a temperature of 750° C. A ferrocene source was heated to a temperature of 150° C. and the sample was exposed to the ferrocene. The sample was then exposed to a mixture of argon (99.9%) at 1000 sccm, hydrogen (99.9%) at 500 sccm and a hydrocarbon (99.9%) (for example, acetylene, ethylene, and/or methane) at 50 sccm for 10-30 minutes. The sample was finally cooled to room temperature and removed from the furnace.

### Example 5

This example provides an exemplary process of making a 3D graphitic matrix based on a nickel template using chemical vapor deposition (CVD). Direct Metal Laser Sintering (DMLS) is used to print a 3D nickel template having the structure pattern of FIG. 1. DMLS uses a small diameter laser to sinter metal powders to form a metallurgic bond. The laser path is controlled by a digital model based on the structure pattern of FIG. 1. By continually adding more layers of nickel powder, a 3D nickel template is printed. The nickel template is then exposed to methane at high temperature so that carbon deposits onto the nickel and diffuses into the metal. Upon cooling of the nickel template, the carbon solubility of nickel decreases and the diffused carbon migrates to the surface to form a coating beginning with single layer graphene and continuing to grow into thin graphite. Once the 3D graphitic matrix having the structure pattern of FIG. 1 is formed, the nickel is etched away.

### Example 6

This example provides process of making 3D graphitic matrix based on a polymer template followed by high temperature pyrolysis including annealing. Polymeric ink, comprising a graphitizable polymer, such as polyamine and polyamide, is used to print a 3D printed polymer template having the structure pattern of FIG. 1. The printing path is controlled by a digital model based on the structure pattern of FIG. 1. By continually adding more layers of polymer, a 3D polymer template is printed. Using a high temperature furnace, the 3D printed polymer template is then converted to amorphous carbon through pyrolysis, which is then further annealed at high temperature (e.g., >2000° C.) to convert the amorphous carbon to a 3D graphite matrix having the structure pattern of FIG. 1.

Other printing processes such as stereolithography (SLA) of photopolymers or the PolyJet process for photopolymers, extrusion printing of thermoplastics, and laser sintering of powder polymers, similar to that used for direct metal laser sintering can be used to print the 3D printed polymer template above. The polymers used can be converted to graphite upon pyrolysis as described above.

### Example 7

This example provides process of making 3D graphitic matrix based on nickel plated polymer template followed by chemical vapor deposition (CVD). The process described in Example 6 above is followed to produce a polymer template having a structure pattern of FIG. 1. The polymer template subsequently goes through electroless nickel plating to form Ni-plated polymer template. This process provides an alternative approach of forming nickel template to the DMLS process described in Example 5. The template thus formed undergoes the CVD process described in Example 5 to form 3D graphitic matrix.

### Specific Embodiments

Disclosed is a method of forming carbon nanotubes on a carbon substrate that comprises depositing a buffer layer on the carbon substrate by atomic layer deposition; depositing a catalyst on the carbon substrate or buffer layer; and contacting the carbon substrate with a working gas at an elevated temperature to thereby form carbon nanotubes on the carbon substrate. The deposition of the buffer layer can come before the deposition of the catalyst, or the deposition of the catalyst can come before the deposition of the buffer layer.

The substrate can be selected from the group consisting of a carbon foam, a graphite foam, and a 3D printed graphite foam. The carbon substrate can be oxygen-plasma treated prior to atomic layer deposition, e.g., oxygen plasma treated for 1-5 minutes prior to atomic layer deposition.

The buffer layer can be from about 2 about 10 nm thick. The buffer layer can be a metal oxide, such as aluminum oxide, silicon oxide, zinc oxide or combinations thereof. The buffer layer can be an about 5 nm thick layer of aluminum oxide.

The catalyst can be deposited by atomic layer deposition, chemical vapor deposition, or from a vapor phase metal source. The catalyst can be an iron catalyst, e.g., derived from ferrocene. The catalyst can be deposited as a layer, e.g., from about 2 to about 20 nm thick. The catalyst can be deposited as particles, e.g., from about 2 to about 20 nm in size.

The carbon nanotubes can be from about 1 to about 500 μm in length and from about 1 to about 50 nm in diameter. The carbon nanotubes can comprise single walled nanotubes, double walled nanotubes, multi walled nanotubes, or a combination thereof.

The working gas can comprises a hydrocarbon gas such as ethylene, acetylene, methane, benzene, toluene or a combination thereof. The working gas can be contacted to the substrate at a rate of from about 1 to about 1000 sccm for from about 1 to about 60 minutes. The elevated temperature at which the substrate is contacted with the working gas can be from about 400 to about 1100° C.

A composition comprising a conformal layer of carbon nanotubes on a porous carbon substrate is also disclosed. The substrate can be selected from the group consisting of a carbon foam, a graphite foam, and a 3D printed graphite foam. The carbon nanotubes can be from about 1 to about 500 μm in length and from about 1 to about 50 nm in diameter. The carbon nanotubes can comprise single walled nanotubes, double walled nanotubes, multi walled nanotubes, or a combination thereof.

A composition comprising a layer of carbon nanotubes on a carbon substrate, filled with a phase change material is also disclosed.

A porous graphitic matrix unit is also disclosed herein. The porous graphitic matrix can have a structure comprising, a hub, a plurality of radius thin walls radiating from the hub, and at least one circumferential thin wall surrounding the hub and intersecting with the radius thin walls to form a matrix comprising a plurality of pores within the matrix, wherein the structure including the hub and the walls of the matrix comprises graphitic carbon. The porous graphitic matrix unit can comprise a plurality of circumferential thin walls concentrically surrounding the hub and intersecting with the radius thin walls to form the plurality of pores within the matrix. The radius thin walls can be substantially perpendicular to a surface of the matrix. The circumferential thin walls can be substantially perpendicular to a surface of the matrix. The hub can comprise a cylindrical opening having a radius R ranging from 0 mm to 10 mm, such as from 1.6 mm to 6.35 mm. The cylindrical opening can allow a tube to go through. The radius thin walls can have a thickness of from 0.02 μm to 1 μm. The circumferential thin walls have a thickness of from 0.01 μm to 1 μm. The pores have an average size from 100 μm to 5000 μm. The porous graphitic matrix unit can have a height of from 0.2 mm to 100 mm. The porous graphitic matrix can have a width, a length, or a diameter from 5 mm to 500 mm.

Also disclosed herein is a porous graphitic matrix unit having a structure comprising a first set of plurality of thin walls and a second set of plurality of thin walls intersecting with the first set of thin walls to form a matrix comprising a plurality of pores within the matrix unit, wherein the structure including the thin walls of the matrix comprises graphitic carbon. The first set of thin walls can have a thickness of from 0.02 μm to 1 μm. The second set of thin walls can have a thickness of from 0.01 μm to 1 μm. The pores within the porous graphitic matrix unit can have an average size from 100 μm to 5000 μm. The porous graphitic matrix unit can further comprise a hub that comprises an opening having a size ranging from 0 mm to 15 mm. The size of the hub can be from 1.6 mm to 10 mm and the opening can allow a tube or shaft to go through. The porous graphitic matrix unit can have a height of from 0.2 mm to 100 mm. The porous graphitic matrix unit can have a width, a length, or a diameter from 5 mm to 500 mm.

Also disclosed herein is a porous graphitic matrix comprising a plurality of the porous graphitic matrix units described herein.

The plurality of porous graphitic matrix units can be stacked together so the hubs are aligned with one another perpendicularly. The hubs can individually comprise a cylindrical opening, and the aligned cylindrical openings of the hubs can form a conduit to allow a tube or shaft to go through. The radius and/or circumferential thin walls of at least two stacked porous graphitic matrix units can be offset from each other.

The plurality of porous graphitic matrix units can be stacked together so the hubs are aligned parallel to each other. The aligned parallel cylindrical openings of the hubs can form parallel conduits, each allowing one tube or shaft to go through.

Also disclosed herein are devices comprising any of the porous graphitic matrixes described herein. The graphitic matrix can having a structure that provides direct radial pathways for heat to travel, the device further comprising a phase change material embedded in the pores of the graphitic matrix. The phase change material can comprise water, aqueous salt solutions, paraffins, salt hydrates, fatty acids, sugar alcohols, or a combination thereof. The device can be a thermal battery, a thermal storage unit, or a heat exchanger. The device can further comprise a plurality of tubes fitted inside the conduits of the matrix. The tubes can carry a working fluid that is in thermal exchange with the phase change material in the pores through the tube and walls of the matrix.

Also disclosed herein is an electrochemical battery comprising an electrode comprising an electrochemically active material embedded in the pores of the graphitic matrix described herein. The graphitic matrix can serve as the current collector of the electrode.

The electrode can be the negative electrode and the electrochemically active material can be the negative electrode active material embedded in the pores of the graphitic matrix. The negative electrode active material can comprise silicon. The positive electrode of the battery can comprise lithium metal oxide.

The electrode can be the positive electrode and the electrochemically active material can be the positive electrode active material embedded in the pores of the graphitic matrix. The negative electrode active material can comprise lithium metal oxide or lithium iron phosphate.

Also disclosed herein is a method of forming a porous graphitic matrix unit. The method can comprise printing a 3D nickel structure based on a structure pattern to form a 3D nickel template and depositing graphite onto the 3D nickel template to form the porous graphitic matrix unit having the structure pattern. The 3D nickel template can be printed through direct metal laser sintering of nickel metal powder. Carbon can be deposited onto the 3D nickel template through chemical vapor deposition. The method can further comprise etching away the nickel template.

The porous graphitic matrix unit can have a structure comprising a first set of plurality of thin walls and a second set of plurality of thin walls intersecting with the first set of thin walls to form a matrix comprising a plurality of pores within the matrix unit, wherein the structure including the thin walls of the matrix comprises graphitic carbon.

The structure pattern of the porous graphitic matrix unit can comprise a hub, a plurality of radius thin walls radiating from the hub, and at least one circumferential thin wall surrounding the hub and intersecting with the radius thin walls to form a matrix comprising a plurality of pores within the matrix, wherein the structure including the hub and the walls of the matrix comprises graphitic carbon.

The structure pattern can provide direct radial pathways for heat to travel.

The method can further comprise assembling a plurality of the porous graphitic matrix units to form a porous graphitic matrix.

Also disclosed herein is a method of forming a porous graphitic matrix unit, the method comprising using polymeric ink to print a 3D polymeric structure based on a structure pattern and pyrolizing and annealing the 3D polymer structure to form the porous graphitic matrix unit having a structure pattern. The polymeric ink can comprise polyamides, polyamines or a combination thereof.

The structure pattern of the porous graphitic matrix unit can comprise a first set of plurality of thin walls and a second set of plurality of thin walls intersecting with the first set of thin walls to form a matrix comprising a plurality of pores within the matrix unit, wherein the structure including the thin walls of the matrix comprises graphitic carbon.

The structure pattern of the porous graphitic matrix unit can comprise a hub, a plurality of radius thin walls radiating from the hub, and at least one circumferential thin wall surrounding the hub and intersecting with the radius thin walls to form a matrix comprising a plurality of pores within the matrix, wherein the structure including the hub and the walls of the matrix can comprise graphitic carbon.

The structure pattern of the porous graphitic matrix unit can provide direct radial pathways for heat to travel.

The method can further comprise assembling a plurality of the porous graphitic matrix units to form a graphitic matrix.

Also disclosed herein is a method of forming a porous graphitic matrix unit, the method comprising, using polymeric ink to print a 3D polymeric structure based on a structure pattern, electroplating the 3D polymeric structure with Cu or Ni to form a 3D metal plated template having the structure pattern, and depositing carbon onto the 3D metal plated template to form the porous graphitic matrix unit having the structure pattern. Carbon can be deposited onto the 3D metal plated template through chemical vapor deposition. The method can further comprise etching away the metal plated template. The polymeric ink can comprise polyamides, polyamines or a combination thereof. The porous graphitic matrix unit can have a structure that can comprise a first set of plurality of thin walls and a second set of plurality of thin walls intersecting with the first set of thin walls to form a matrix comprising a plurality of pores within the matrix unit, wherein the structure including the thin walls of the matrix comprises graphitic carbon. The structure pattern of the porous graphitic matrix unit can comprises a hub, a plurality of radius thin walls radiating from the hub, and at least one circumferential thin wall surrounding the hub and intersecting with the radius thin walls to form a matrix comprising a plurality of pores within the matrix, wherein the structure including the hub and the walls of the matrix can comprise graphitic carbon. The structure pattern can provide direct radial pathways for heat to travel. The method can further comprise assembling a plurality of the porous graphitic matrix units to form a graphitic matrix.

The materials and methods of the appended claims are not limited in scope by the specific materials and methods described herein, which are intended as illustrations of a few aspects of the claims and any materials and methods that are functionally equivalent are within the scope of this disclosure. Various modifications of the materials and methods in addition to those shown and described herein are intended to fall within the scope of the appended claims. Further, while only certain representative materials, methods, and aspects of these materials and methods are specifically described, other materials and methods and combinations of various features of the materials and methods are intended to fall within the scope of the appended claims, even if not specifically recited. Thus a combination of steps, elements, components, or constituents can be explicitly mentioned herein; however, all other combinations of steps, elements, components, and constituents are included, even though not explicitly stated.

Other than where noted, all numbers expressing geometries, dimensions, and so forth used in the specification and claims are to be understood at the very least, and not as an attempt to limit the application of the doctrine of equivalents to the scope of the claims, to be construed in light of the number of significant digits and ordinary rounding approaches. Unless defined otherwise, all technical and scientific terms used herein have the same meanings as commonly understood by one of skill in the art to which the disclosed invention belongs. Publications cited herein and the materials for which they are cited are specifically incorporated by reference.

What is claimed is:

1. A composition comprising galactitol and mannitol in a weight ratio of from about 9:1 to about 1:9.

2. The composition of claim 1, wherein the weight ratio of galactitol to mannitol is from about 2.5:1 to about 1:1.5.

3. The composition of any of claims 1-2, wherein the weight ratio of galactitol to mannitol is about 1:1.

4. The composition of any of claims 1-3, wherein the amount of galactitol and mannitol is at least about 75 wt. % of the total composition.

5. The composition of any of claims 1-4, wherein the amount of galactitol and mannitol is at least about 90 wt. % of the total composition.

6. The composition of any of claims 1-5, wherein the amount of galactitol and mannitol is at least about 98 wt. % of the total composition.

7. The composition of any of claims 1-6, wherein the composition has a melting point of from about 150° C. to about 160° C.

8. The composition of any of claims 1-7, wherein the composition has a melting point of from about 151° C. to about 153° C.

9. The composition of any of claims 1-8, wherein the composition has a latent heat of fusion of from about 280 J/g to about 315 J/g.

10. The composition of any of claims 1-9, wherein the composition has a melting point of from about 300 J/g to about 310 J/g.

11. The composition of any of claims 1-10, wherein the galactitol and/or mannitol is oxidized, reduced, or functionalized with an alkyl, amino, amido, cyano, thio, or ester group at one or more positions.

12. The composition of any of claims 1-11, further comprising one or more of a viscosity modifier, an antimicrobial material, a fire retardant, an agent to prevent supercooling, a thickener, an antioxidant, or a corrosion inhibitor.

13. The composition of any of claims 1-12, further comprising one or more thermal storage materials selected from the group consisting of fatty acid, paraffin, polyethylene glycol, polyvinyl alcohol, glycerin, polyethylene, and crosslinked polyethylene.

14. A microcapsule comprising the composition of any of claims 1-13.

15. A thermal composite comprising the composition of any of claims 1-13 and a thermal conductivity modulator.

16. The thermal composite of claim 15, wherein the thermal conductivity modulator comprises a metal or metal oxide.

17. The thermal composite of claim 15, wherein the thermal conductivity modulator comprises a graphitic foam.

18. The thermal composite of claim 15, wherein the graphitic foam is a hybrid ultrathin graphitic foam comprising nanotubes.

19. A thermal storage device comprising the composition of any of claims 1-13, the microcapsule of claim 14, or the thermal composite of any of claims 15-18.

20. The thermal storage device of claim 19, wherein the device is a shell tube device.

21. A method of forming carbon nanotubes on a carbon substrate, comprising:
a. depositing a buffer layer on the carbon substrate by atomic layer deposition;
b. depositing a catalyst on the carbon substrate and/or buffer layer; and
c. contacting the carbon substrate with a working gas at an elevated temperature to thereby form carbon nanotubes on the carbon substrate.

22. The method of claim 21, wherein step a) is performed before step b).

23. The method of claim 21, wherein step b) is performed before step a).

24. The method of any of claims 21-23, wherein the carbon substrate is a carbon foam.

25. The method of any of claims 21-24, wherein the carbon substrate is a graphite foam.

26. The method of any of claims 21-25, wherein the carbon substrate is a graphite foam formed by chemical vapor deposition of graphene on a nickel foam, and the nickel is removed by electrolytic etching.

27. The method of any of claims 21-26, wherein the carbon substrate is a 3D printed graphite foam.

28. The method of any of claims 21-27, wherein the buffer layer is about 1 to about 10 nm thick.

29. The method of any of claims 21-28, wherein the buffer layer is about 5 nm thick.

30. The method of any of claims 21-29, wherein the buffer layer comprises a metal oxide.

31. The method of any of claims 21-30, wherein the buffer layer comprises aluminum oxide, zinc oxide, silicon oxide, or combinations thereof.

32. The method of any of claims 21-31, wherein the buffer layer comprises aluminum oxide.

33. The method of any of claims 21-32, wherein the buffer layer comprises a layer of aluminum oxide from about 2 to about 10 nm thick.

34. The method of any of claims 21-33, wherein the buffer layer comprises a layer of aluminum oxide about 5 nm thick.

35. The method of any of claims 21-34, wherein the catalyst is an iron catalyst.

36. The method of any of claims 21-35, wherein the catalyst is formed from ferrocene.

37. The method of any of claims 21-36, wherein the catalyst is deposited as a layer.

38. The method of any of claims 21-37, wherein the catalyst is deposited as a layer from about 2 to about 20 nm thick.

39. The method of any of claims 21-38, wherein the catalyst is deposited as particles.

40. The method of any of claims 21-39, wherein the catalyst is deposited as particles from about 2 to about 20 nm in size.

41. The method of any of claims 21-40, wherein the catalyst is deposited using atomic layer deposition.

42. The method of any of claims 21-41, wherein the catalyst is deposited using chemical vapor deposition.

43. The method of any of claims 21-42, wherein the catalyst is deposited by a vapor phase metal source.

44. The method of any of claims 21-43, wherein the carbon nanotubes are from 1 about to about 500 micrometers in length.

45. The method of any of claims 21-44, wherein the carbon nanotubes are from about 250 to about 500 micrometers in length.

46. The method of any of claims 21-45, wherein the carbon nanotubes are from about 1 to about 50 nm in diameter.

47. The method of any of claims 21-46, wherein the carbon nanotubes are about 10 nm in diameter.

48. The method of any of claims 21-47, wherein the carbon nanotubes comprise single walled nanotubes, double walled nanotubes, multi walled nanotubes, or a combination thereof.

49. The method of any of claims 21-48, wherein the carbon substrate is plasma treated prior to atomic layer deposition.

50. The method of any of claims 21-49, wherein the carbon substrate is oxygen-plasma treated prior to atomic layer deposition.

51. The method of any of claims 21-50, wherein the carbon substrate is oxygen-plasma treated for from about 1 to about 5 minutes prior to atomic layer deposition.

52. The method of any of claims 21-51, wherein the working gas comprises a hydrocarbon gas.

53. The method of any of claims 21-52, wherein the working gas comprises ethylene, acetylene, methane, benzene, toluene or a combination thereof.

54. The method of any of claims 21-53, where in the working gas is flowed at a rate of about 1 to about 1000 sccm over the carbon substrate.

55. The method of any of claims 21-54, wherein the temperature remains elevated and the working gas is flowed for from about 1 to about 60 minutes.

56. The method of any of claims 21-55, wherein the elevated temperature is from about 400° C. to about 1100° C.

57. A composition comprising: a conformal layer of carbon nanotubes on a porous substrate.

58. The composition of claim 57, wherein the porous substrate is a metal foam.

59. The composition of any of the claims 57-58, wherein the porous substrate is a carbon foam.

60. The composition of any of the claims 57-59, wherein the porous substrate is a graphite foam.

61. The composition of any of the claims 57-60, wherein the porous substrate is a 3D printed graphite foam.

62. The composition of any of the claims 57-61, wherein the carbon nanotubes are from about 1 to about 500 micrometers in length.

63. The composition of any of the claims 57-62, wherein the carbon nanotubes are from about 250 to about 500 micrometers in length.

64. The composition of any of the claims 57-63, wherein the carbon nanotubes are from about 1 to about 50 nm in diameter.

65. The composition of any of the claims 57-64, wherein the carbon nanotubes comprise single walled nanotubes, double walled nanotubes, multi walled nanotubes, or a combination thereof.

66. A composition comprising: a layer of carbon nanotubes on a carbon substrate and a phase change material.

67. A method for contacting a phase change material with a composition comprising a layer of carbon nanotubes on a carbon substrate, comprising plasma treating the layer of carbon nanotubes on a carbon substrate.

68. A method of use of the material from any of claims 21-66 as a thermal conductivity substrate for flexible graphene electronic devices.

69. A method of use of the material from any of claims 21-66 as an electrode in a battery.

70. A method of use of the material from any of claims 21-66 in a thermal storage device.

71. A method of use of the material from any of claims 21-66 in a heat exchange device.

72. A method of use of the material from any of claims 21-66 with a phase change material in a thermal storage unit.

73. A thermal storage unit comprising:
a heat exchange path through which a heat exchange medium flows; and
a thermal storage medium in thermal contact with the heat exchange path;
wherein the thermal storage medium comprises a composite which comprises a porous thermally conductive matrix and a phase change material disposed within the porous thermally conductive matrix.

74. The unit of claim 73, wherein the heat exchange path comprises a tube having a central axis and a tube wall having an inner surface and an outer surface, wherein the tube wall is coaxially disposed about the central axis so as to define a lumen through which the heat exchange medium flows.

75. The unit of claim 74, wherein the thermal storage medium is in physical contact with the outer surface of the tube.

76. The unit of claim 74 or 75, wherein the thermal storage medium surrounds the tube.

77. The unit of any of claims 73-76, wherein the porous thermally conductive matrix comprises an isotropic thermally conductive matrix.

78. The unit of any of claims 73-76, wherein the porous thermally conductive matrix comprises an anisotropic thermally conductive matrix.

79. The unit of claim 78, wherein the anisotropic thermally conductive matrix comprises a thermally conductive matrix configured to exhibit increased thermal conductivity along an axis orthogonal to heat exchange path relative to the thermal conductivity along an axis parallel to heat exchange path.

80. The unit of claim 78 or 79, wherein the anisotropic thermally conductive matrix comprises a thermally conductive matrix configured to exhibit increased thermal conductivity along a plurality of axes radially extending from the heat exchange path relative to the thermal conductivity along an axis parallel to heat exchange path.

81. The unit of any of claims 73-80, wherein the porous thermally conductive matrix comprises a graphite foam, a carbon foam, a 3D-printed graphite matrix, a metal foam, or combinations thereof.

82. The unit of claim 81, wherein the graphite foam, the carbon foam, the 3D-printed graphite matrix, the metal foam, or combinations thereof further comprises a conformal layer of carbon nanotubes disposed on the graphite foam, the carbon foam, the 3D-printed graphite matrix, the metal foam, or combinations thereof.

83. The unit of any of claims 73-82, wherein the phase change material has a melting temperature of from about 50° C. to about 225° C.

84. The unit of any of claims 73-83, wherein the phase change material has a melting enthalpy of from about 200 MJ/m³ to about 400 MJ/m³.

85. The unit of any of claims 73-84, wherein the phase change material comprises a sugar alcohol or a blend of sugar alcohols.

86. The unit of any of claims 73-85, wherein the phase change material comprises a blend of mannitol and galactitol.

87. The unit of any of claims 73-86, further comprising a plurality of heat exchange paths through which a heat exchange medium flows.

88. The unit of claim 87, wherein each heat exchange path comprises a tube having a central axis and a tube wall having an inner surface and an outer surface, wherein the tube wall is coaxially disposed about the central axis so as to define a lumen through which the heat exchange medium flows, and wherein the central axes of each of the tubes are substantially parallel to each other.

89. The unit of any of claims 73-88, further comprising a housing enclosing the heat exchange path and the thermal storage medium.

90. The unit of claim 89, further comprising an inlet port and an outlet port for transferring a heat exchange medium to the heat exchange path.
